(19) United States
(12) Patent Application Publication
(10) Pub. No.: US 2026/0060124 A1
(43) Pub. Date: Feb. 26, 2026

(54) METALLIZED CERAMIC SUBSTRATE AND MANUFACTURING METHOD THEREOF

(71) Applicant: TONG HSING ELECTRONIC INDUSTRIES, LTD., Taoyuan City (TW)

(72) Inventors: Jia-Zheng Xu, Taoyuan City (TW); JHIH-WEI LAI, Taoyuan City (TW); CHUN-CHIEH LIAO, Taoyuan City (TW); JIAN-YU SHIH, Taoyuan City (TW)

(21) Appl. No.: 18/979,668

(22) Filed: Dec. 13, 2024

(30) Foreign Application Priority Data
Aug. 23, 2024 (TW) 113131720

(51) Int. Cl. H01L 23/15; H01L 21/48; H01L 23/498

(52) U.S. Cl. CPC H01L 23/15; H01L 21/4857; H01L 23/49822

(57) ABSTRACT

A metallized ceramic substrate and a manufacturing method thereof are provided. The manufacturing method includes providing a ceramic substrate layer; performing a first selective plating operation that forms at least one electrode metal structure protruding on a surface of the ceramic substrate layer based on a first selective plating area defined by a first pattern mask, in which an outer layer of the at least one electrode metal structure away from the ceramic substrate layer is a thin gold layer having a first thickness; and performing a second selective plating operation that forms a thick gold layer on the thin gold layer based on a second selective plating area defined by a second pattern mask, in which the thick gold layer has a second thickness greater than the first thickness.

### CROSS-REFERENCE TO RELATED PATENT APPLICATION

This application claims the benefit of priority to Taiwan Patent Application No. 113131720, filed on Aug. 23, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a metallized ceramic substrate, and more particularly to a metallized ceramic substrate and a manufacturing method thereof.

### BACKGROUND OF THE DISCLOSURE

In the relevant art, metallized ceramic substrates are widely used in semiconductor chip packaging due to their excellent heat dissipation, insulation, and corrosion resistance properties.

However, the conventional manufacturing processes for metallized ceramic substrates continue to encounter challenges. First of all, these processes often require additional conductor connections, which can cause burrs during the subsequent cutting stages. This results in uneven product edges, ultimately affecting both the reliability and quality of the final products.

Moreover, in the relevant art, the electroplating process for metallized ceramic substrates typically involves multiple steps to form the necessary conductive layer. This not only increases the manufacturing time and costs, but also complicates the overall process. In some applications, the substrate may not provide adequate bonding strength during component attachment (e.g., die bonding or wire bonding), leading to decreased packaging reliability and negatively affecting the performance of semiconductor chips after packaging.

Therefore, simplifying the process, preventing burr-related issues, and improving packaging reliability are important technical issues that need to be addressed in the field of metallized ceramic substrate manufacturing.

### SUMMARY OF THE DISCLOSURE

In response to the above-referenced technical inadequacies, the present disclosure provides a metallized ceramic substrate and a manufacturing method thereof.

In order to solve the above-mentioned problems, one of the technical aspects adopted by the present disclosure is to provide a method for manufacturing a metallized ceramic substrate that includes: providing a ceramic substrate layer; performing a first selective plating operation; and performing a second selective plating operation.

The first selective plating operation includes: forming at least one electrode metal structure protruding on a surface of the ceramic substrate layer based on a first selective plating area of a first pattern mask, in which an outer layer of the at least one electrode metal structure away from the ceramic substrate layer is a thin gold layer, and the thin gold layer has a first thickness.

The second selective plating operation includes: forming a thick gold layer on the thin gold layer of the at least one electrode metal structure based on a second selective plating area of a second pattern mask, in which the thick gold layer has a second thickness, and the second thickness is greater than the first thickness.

In order to solve the above-mentioned problems, another one of the technical aspects adopted by the present disclosure is to provide a metallized ceramic substrate that includes a ceramic substrate layer, at least one electrode metal structure, and a thick gold layer.

The at least one electrode metal structure is protrudingly disposed on a surface of the ceramic substrate layer, in which an outer layer of the at least one electrode metal structure away from the ceramic substrate layer is a thin gold layer, and the thin gold layer has a first thickness.

The thick gold layer is formed on the thin gold layer, in which the thick gold layer has a second thickness, and the second thickness is greater than the first thickness.

Therefore, the first pattern mask and the second pattern mask of the present disclosure can be used in combination to form thick gold structures in the first selective plating area and the second selective plating area, which are necessary for subsequent processes involving die bonding or wire bonding.

The metallized ceramic substrate of the embodiments of the present disclosure addresses several technical challenges, including eliminating the need for tie bar conductors, effectively resolving the issue of burrs created during the singulation process.

The manufacturing process can be streamlined by replacing the solder ball mounting step with electroplating or electroless plating of thick gold layers. Additionally, costs can be reduced by selectively patterning the thick gold plating according to practical requirements. Furthermore, the reliability of the substrate is enhanced by minimizing copper exposure, improving corrosion resistance, and increasing oxidation resistance.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIGS. 1A to 1C are flow diagrams of a manufacturing method of a metallized ceramic substrate according to a first embodiment of the present disclosure;

FIGS. 2A to 2D are flow diagrams of a manufacturing method of a metallized ceramic substrate according to a second embodiment of the present disclosure;

FIGS. 3A to 3D are flow diagrams of a manufacturing method of a metallized ceramic substrate according to a third embodiment of the present disclosure;

FIGS. 4A to 4C are flow diagrams of a manufacturing method of a metallized ceramic substrate according to a fourth embodiment of the present disclosure;

FIGS. 5A to 5C are flow diagrams of a manufacturing method of a metallized ceramic substrate according to a fifth embodiment of the present disclosure;

FIGS. 6A to 6C are flow diagrams of a manufacturing method of a metallized ceramic substrate according to a sixth embodiment of the present disclosure;

FIGS. 7A to 7C are flow diagrams of a manufacturing method of a metallized ceramic substrate according to a seventh embodiment of the present disclosure;

FIGS. 8A to 8D are flow diagrams of a manufacturing method of a metallized ceramic substrate according to an eighth embodiment of the present disclosure;

FIGS. 9A to 9C are flow diagrams of a manufacturing method of a metallized ceramic substrate according to a ninth embodiment of the present disclosure; and

FIGS. 10A to 10C are flow diagrams of a manufacturing method of a metallized ceramic substrate according to a tenth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Manufacturing Method of Metallized Ceramic Substrate

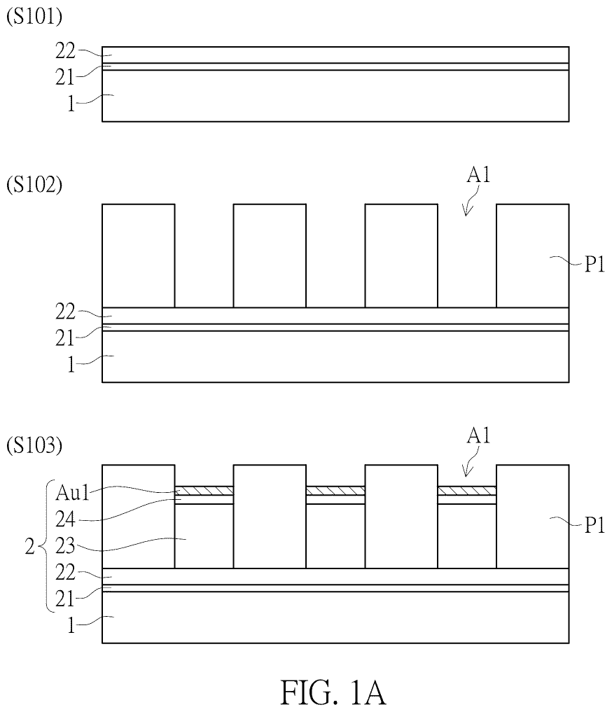

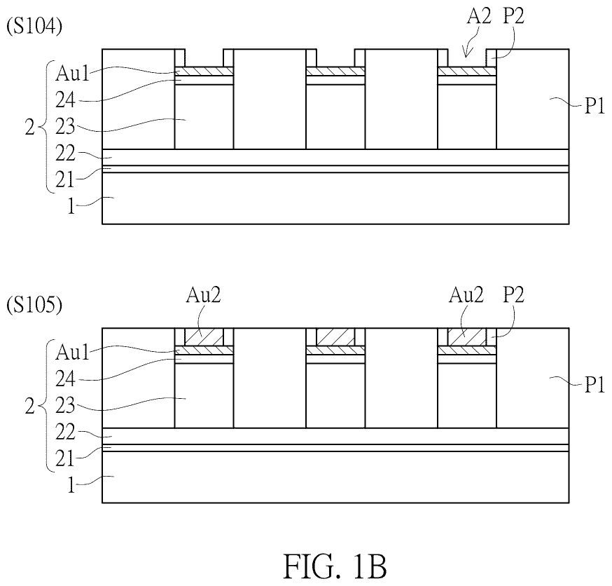

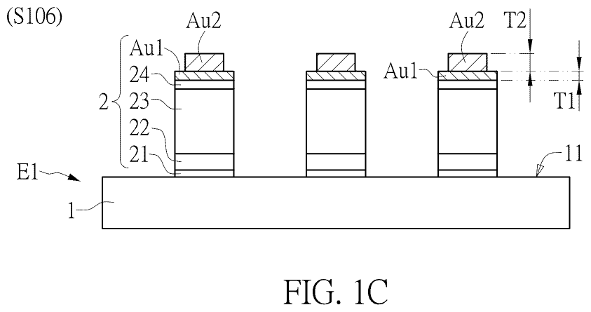

Referring to FIGS. 1 to 10, a first embodiment to a tenth embodiment of the present disclosure respectively provides a manufacturing method of a metallized ceramic substrate. The manufacturing method of each of the first embodiment to the tenth embodiment at least includes a first step, a second step, and a third step.

The first step includes providing a ceramic substrate layer 1.

The second step includes performing a first selective plating operation, which includes forming at least one electrode metal structure 2, 2′, 2″ protruding on a surface 11 of the ceramic substrate layer 1 based on a first selective plating area A1 of a first pattern mask P1. An outer layer of the at least one electrode metal structure 2, 2′, 2″ away from the ceramic substrate layer 1 is a thin gold layer Au1, Au1′, and the thin gold layer Au1, Au1′ has a first thickness T1.

The third step includes performing a second selective plating operation, which includes forming a thick gold layer Au2, Au21, Au22, Au2′, Au21′, Au22′ on the thin gold layer Au1, Au1′ of the at least one electrode metal structure 2, 2′, 2″ based on a second selective plating area A2 of a second pattern mask P2. The thick gold layer Au2, Au21, Au22, Au2′, Au21′, Au22′ has a second thickness T2, and the second thickness T2 of the thick gold layer Au2, Au21, Au22, Au2′, Au21′, Au22′ is greater than the first thickness T1 of the thin gold layer Au1, Au1′.

### Metallized Ceramic Substrate

In addition, each of the first embodiment to the tenth embodiment of the present disclosure also provides a metallized ceramic substrate E1 to E10, which includes a ceramic substrate layer 1 and at least one electrode metal structure 2, 2′, 2″ disposed and protruding on a surface 11 of the ceramic substrate layer 1.

An outer layer of the at least one electrode metal structure 2, 2′, 2″ away from the ceramic substrate layer 1 (or an outer layer being not in contact with the ceramic substrate layer 1) is a thin gold layer Au1, Au1′. Furthermore, the metallized ceramic substrate E1 to E10 includes a thick gold layer Au2, Au21, Au22, Au2′, Au21′, Au22′ formed on the thin gold layer Au1, Au1′ of the at least one electrode metal structure 2, 2′, 2″. The thick gold layer Au2, Au21, Au22, Au2′, Au21′, Au22′ is in direct contact with the thin gold layer Au1, Au1′.

Moreover, the second thickness T2 of the thick gold layer Au2, Au21, Au22, Au2′, Au21′, Au22′ is greater than the first thickness T1 of the thin gold layer Au1, Au1′. The first thickness T1 of the thin gold layer Au1, Au1′ is between 0.06 micrometers and 0.2 micrometers. The second thickness T2 of the thick gold layer Au2, Au21, Au22, Au2′, Au21′, Au22′ is between 0.5 micrometers and 25 micrometers, preferably between 1 micrometer and 25 micrometers, and more preferably between 3 micrometers and 25 micrometers. For example, the second thickness T2 is 5 micrometers, 10 micrometers, 15 micrometers, 20 micrometers, or 25 micrometers, but the present disclosure is not limited thereto.

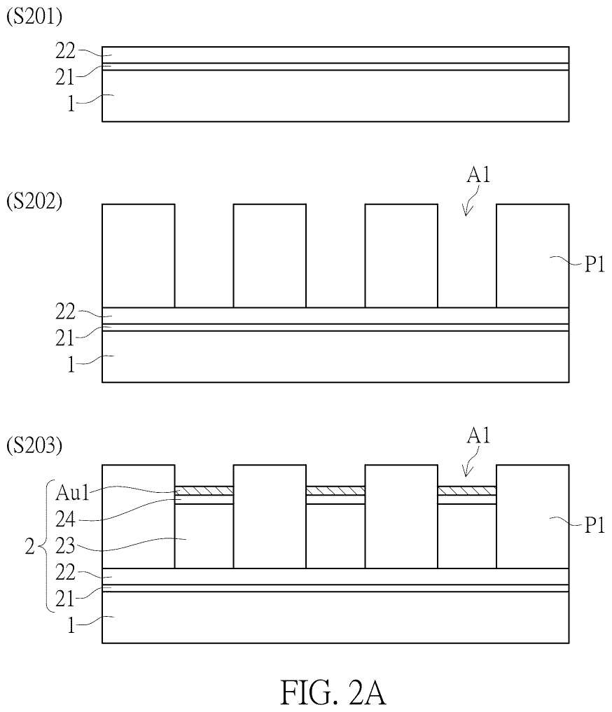

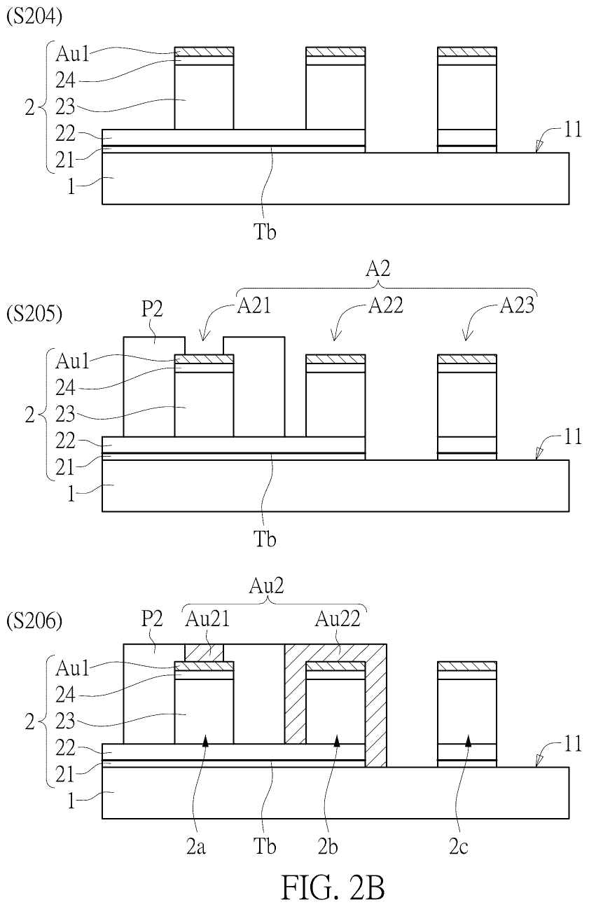

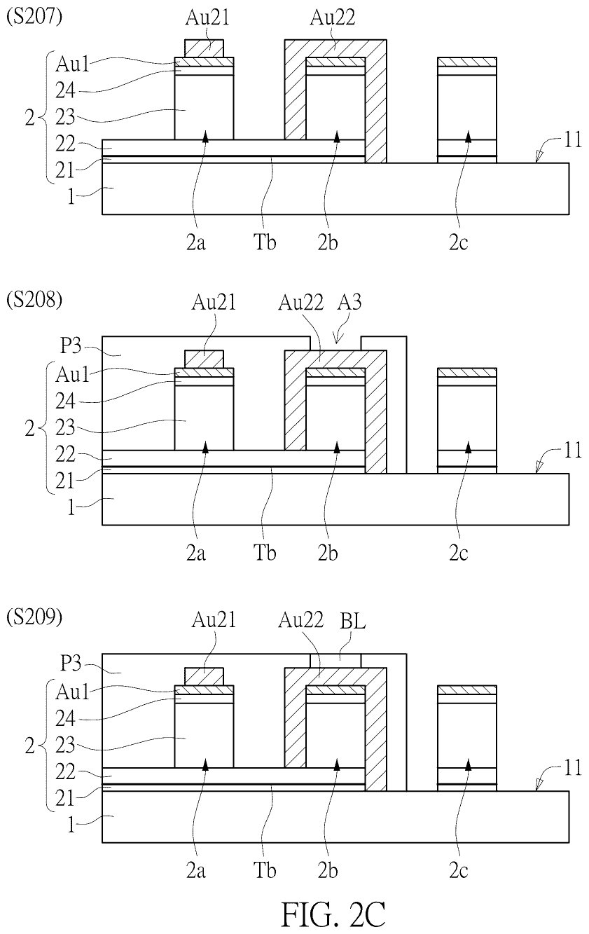

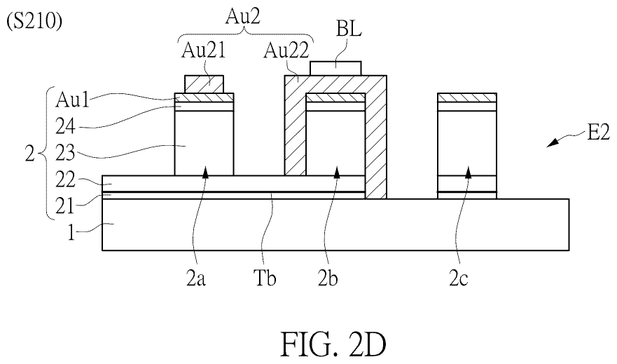

In some embodiments of the present disclosure, the thick gold layer Au2, Au2′ is a protruded thick gold Au21, Au21′, which is partially disposed on a top surface of the thin gold layer Au1, Au1′, and exposes part of the top surface of the thin gold layer Au1, Au1′. Therefore, the thick gold layer Au2, Au2′, Au21, Au21′ and the thin gold layer Au1, Au1′ together form a protruding structure, which can be defined as a protruded thick gold electrode metal structure 2a, 2a′, 2a″ as shown in FIGS. 2D, 4C, 5C, 7C, 9C.

In some other embodiments of the present disclosure, the thick gold layer Au2, Au2′ is a covered thick gold Au22, Au22′, which completely covers the top surface of the thin gold layer Au1, Au1′, and the covered thick gold Au22, Au22′ extends to cover sidewalls of the electrode metal structure 2, 2′, 2″, to fully cover the outer surfaces of the electrode metal structure 2, 2′, 2″, thereby forming an inverted U-shaped structure, which can be defined as a covered thick gold electrode metal structure 2b, 2b′, 2b″ as shown in FIGS. 2D, 3D, 6C, 8D, 10C.

Overall, the metallized ceramic substrate and the manufacturing method thereof in the embodiments of the present disclosure produce a novel DPC (i.e., Direct Plated Copper) metallized ceramic substrate by selectively patterning the thick gold layer on the thin gold layer through electroplating or chemical plating (i.e., electroless plating).

The first pattern mask P1 and the second pattern mask P2 can be used in conjunction to form the thick gold structure in the areas that require die bonding or wire bonding during subsequent processes through the first selective plating area A1 and the second selective plating area A2.

The metallized ceramic substrate E1 to E10 of the embodiments of the present disclosure addresses several technical challenges, including eliminating the need for tie bar conductors, effectively resolving the issue of burrs created during the singulation process. The manufacturing process can be streamlined by replacing the solder ball mounting step with electroplating or electroless plating of thick gold layers. Additionally, costs can be reduced by selectively patterning the thick gold plating according to practical requirements. Furthermore, the reliability of the substrate is enhanced by minimizing copper exposure, improving corrosion resistance, and increasing oxidation resistance.

To better understand the embodiments of the present disclosure, the manufacturing methods of the metallized ceramic substrates E1 to E10 from the first to the tenth embodiments will be further explained in detail below.

### First Embodiment

Referring to FIGS. 1A to 1C, the manufacturing method of the metallized ceramic substrate E1 of the first embodiment of the present disclosure includes steps S101 to S106.

As shown in FIG. 1A, step S101 includes providing a ceramic substrate layer 1, and sequentially forming a first metal layer 21 and a second metal layer 22 on a surface 11 of the ceramic substrate layer 1. In other words, the first metal layer 21 is formed on the surface 11 of the ceramic substrate layer 1, and the second metal layer 22 is formed on the first metal layer 21.

The ceramic substrate layer 1 can be, for example, an aluminum nitride (AlN) ceramic substrate layer, an alumina (Al₂O₃) ceramic substrate layer, a silicon nitride (SiN) ceramic substrate layer, or a silicon carbide (SiC) ceramic substrate layer, but the present disclosure is not limited thereto.

Furthermore, the first metal layer 21 is a sputtered titanium (Ti) layer, and the second metal layer 22 is a sputtered copper (Cu) layer. Specifically, the first metal layer 21 and the second metal layer 22 can be sequentially formed by sputtering titanium and sputtering copper, respectively, to fully cover the surface 11 of the ceramic substrate layer 1, thereby completing a copper clad process for the ceramic substrate layer, but the present disclosure is not limited thereto.

Further, a first selective plating operation is performed, which includes steps S102 to S103.

Step S102 includes forming a first pattern mask P1 on the ceramic substrate layer 1, in which the first pattern mask P1 defines a first selective plating area A1, and the first selective plating area A1 at least partially exposes the surface of the second metal layer 22 (sputtered copper layer).

The first pattern mask P1 is a protective mask layer having a pattern, and the material of the first pattern mask P1 can be a dry film, a photoresist, a tape, or a solder resist, but the present disclosure is not limited thereto.

Step S103 includes sequentially forming a third metal layer 23, a fourth metal layer 24, and a thin gold layer Au1 stacked on an exposed copper surface of the second metal layer 22 (i.e., the sputtered copper layer) through electroplating, based on the first selective plating area A1 defined by the first pattern mask P1.

The third metal layer 23 is an electroplated copper (Cu) layer, the fourth metal layer 24 is an electroplated nickel (Ni) layer, and the thin gold layer Au1 is an electroplated thin gold (Au) layer.

Accordingly, based on the first selective plating area A1 of the first pattern mask P1, at least one electrode metal structure 2 can be formed and protruded on the surface 11 of the ceramic substrate layer 1. The at least one electrode metal structure 2 sequentially includes the first metal layer 21 (i.e., sputtered titanium layer), the second metal layer 22 (i.e., sputtered copper layer), the third metal layer 23 (i.e., electroplated copper layer), the fourth metal layer 24 (i.e., electroplated nickel layer), and the thin gold layer Au1 from a direction approaching to away from the ceramic substrate layer 1, in which the thin gold layer Au1 has a first thickness T1. In other words, an outer layer of the electrode metal structure 2 away from the ceramic substrate layer 1 is the thin gold layer Au1. In the present embodiment, a quantity of the electrode metal structure 2 is plural as shown in FIG. 1A, where three electrode metal structures 2 are displayed, but the present disclosure is not limited thereto.

Further, a second selective plating operation is performed, which includes steps S104 to S106.

As shown in FIG. 1B, step S104 includes forming a second pattern mask P2, in which the second pattern mask P2 defines a second selective plating area A2, and the second selective plating area A2 at least partially exposes the surface of the thin gold layer Au1 of the at least one electrode metal structure 2, so as to define a thick gold layer electroplating area on the thin gold layer Au1.

In the present embodiment, the second pattern mask P2 is formed inside the first selective plating area A1 of the first pattern mask P1. The second pattern mask P2 partially covers the surface of the thin gold layer Au1 and partially exposes the surface of the thin gold layer Au1, thereby defining the second selective plating area A2 on the surface of the thin gold layer Au1. In addition, a top surface of the second pattern mask P2 is substantially aligned (flush) with a top surface of the first pattern mask P1, but the present disclosure is not limited thereto.

The second pattern mask P2 is a protective mask layer having a pattern, and the material of the second pattern mask P2 can be, for example, a dry film, a photoresist, a tape, or a solder resist, but the present disclosure is not limited thereto.

Step S105 includes forming a thick gold layer Au2 on the thin gold layer Au1 of the at least one electrode metal structure 2 based on the second selective plating area A2 of the second pattern mask P2. The thick gold layer Au2 has a second thickness T2, and the second thickness T2 of the thick gold layer Au2 is greater than the first thickness T1 of the thin gold layer Au1 as shown in FIG. 1C.

In the present embodiment, the thick gold layer Au2 is partially disposed on the top surface of the thin gold layer Au1, leaving part of the top surface of the thin gold layer Au1 exposed. Accordingly, the thick gold layer Au2 and the thin gold layer Au1 together form a protruding structure, which is defined as a protruded thick gold electrode metal structure 2a. In other words, a width of the thick gold layer Au2 is less than a width of the thin gold layer Au1, so as to form the protruding structure.

In addition, the thick gold layer Au2 can be formed by electroplating or chemical plating (i.e., electroless plating). In the present embodiment, the thick gold layer Au2 is preferably formed by electroplating, and the thick gold layer Au2 has a second thickness T2 of between 0.5 micrometers and 25 micrometers.

As shown in FIG. 1C, step S106 includes stripping off (or removing) the first pattern mask P1 and the second pattern mask P2, and then etching and removing exposed portions of the first metal layer 21 (i.e., the sputtered titanium layer) and the second metal layer 22 (i.e., the sputtered copper layer) that are not covered by the third metal layer 23, to at least partially expose the surface 11 of the ceramic substrate layer 1, thereby completing the preparation of the metallized ceramic substrate E1 of the first embodiment. Accordingly, the metallized ceramic substrate E1 of the present embodiment includes a plurality of electrode metal structures 2 that are independently disposed on the ceramic substrate layer 1. For example, three electrode metal structures 2 are independently disposed on the ceramic substrate layer 1 in the present embodiment, but the present disclosure is not limited thereto.

### Second Embodiment

Referring to FIGS. 2A to 2D, the manufacturing method of the metallized ceramic substrate E2 according to the second embodiment of the present disclosure includes steps S201 to S210.

As shown in FIG. 2A, step S201 includes providing a ceramic substrate layer 1, and sequentially forming a first metal layer 21 (i.e., a sputtered titanium layer) and a second metal layer 22 (i.e., a sputtered copper layer) on a surface 11 of the ceramic substrate layer 1.

A first selective plating operation is performed, which includes steps S202 to S203.

Step S202 includes forming a first pattern mask P1 on the ceramic substrate layer 1, in which the first pattern mask P1 defines a first selective plating area A1, and the first selective plating area A1 at least partially exposes the surface of the second metal layer 22 (i.e., the sputtered copper layer).

Step S203 includes sequentially forming a third metal layer 23 (i.e., an electroplated copper layer), a fourth metal layer 24 (i.e., an electroplated nickel layer), and a thin gold layer Au1 on an exposed copper surface of the second metal layer 22 (i.e., the sputtered copper layer) through electroplating, based on the first selective plating area A1 of the first pattern mask P1, thereby forming at least one electrode metal structure 2 that protrudes on the surface 11 of the ceramic substrate layer 1.

In the present embodiment, the quantity of the at least one electrode metal structure 2 is plural, and a plurality of electrode metal structures 2 can include at least one first electrode metal (e.g., the left electrode metal structure 2 in FIG. 2A), at least one second electrode metal (e.g., the middle electrode metal structure 2 in FIG. 2A), and at least one third electrode metal (e.g., the right electrode metal structure 2 in FIG. 2A).

As shown in FIG. 2B, step S204 includes stripping off (or removing) the first pattern mask P1 from the ceramic substrate layer 1, and selectively etching and removing exposed portions of the first metal layer 21 (i.e., the sputtered titanium layer) and the second metal layer 22 (i.e., the sputtered copper layer) to at least partially expose the surface 11 of the ceramic substrate layer 1 while leaving part of the first metal layer 21 and the second metal layer 22, thereby forming a metal connection layer Tb that is connected to the bottom of the first electrode metal (e.g., the left electrode metal structure 2) and the bottom of the second electrode metal (e.g., the middle electrode metal structure 2), thus maintaining electrical connection between the first electrode metal and the second electrode metal.

A second selective plating operation is performed, which includes steps S205 to S207.

Step S205 includes forming a second pattern mask P2 above the surface 11 of the ceramic substrate layer 1. The second pattern mask P2 defines a second selective plating area A2, which further includes a protruded thick gold plating area A21, a covered thick gold plating area A22, and a non-plating area A23.

More specifically, the second pattern mask P2 partially covers and partially exposes the top surface of the first electrode metal (e.g., the left electrode metal structure 2) to define the protruded thick gold plating area A21 on the thin gold layer Au1 of the first electrode metal. Additionally, the second pattern mask P2 completely exposes the sidewalls and surface of the thin gold layer Au1 of the second electrode metal (e.g., the middle electrode metal structure 2) to define the covered thick gold plating area A22 on an exterior of the second electrode metal. Furthermore, the second pattern mask P2 does not cover the third electrode metal (e.g., the right electrode metal structure 2), and the bottom of the third electrode metal does not connect to the metal connection layer Tb, thus defining the non-plating area A23.

Step S206 includes electroplating a thick gold layer Au2 on the surface of the thin gold layer Au1 of the first electrode metal (e.g., the left electrode metal structure 2) based on the protruded thick gold plating area A21 of the second selective plating area A2 of the second pattern mask P2 and the metal connection layer Tb connected to the bottom of the first electrode metal and the bottom of the second electrode metal, thereby forming a protruded thick gold Au21, which can form a protruding structure together with the thin gold layer Au1, and can be defined as a protruded thick gold electrode metal structure 2a.

The sidewalls of the second electrode metal (e.g., the middle electrode metal structure 2) and a top surface of the thin gold layer Au1 are electroplated based on the covered thick gold plating area A22 to form another thick gold layer Au2, which is defined as a covered thick gold Au22.

Specifically, the covered thick gold Au22 completely covers the top surface of the thin gold layer Au1 of the second electrode metal and extends to cover the sidewalls of the second electrode metal, thereby encapsulating the second electrode metal, forming a substantially inverted U-shaped structure and can be defined as a covered thick gold electrode metal structure 2b.

Further, one end (e.g., the left end) of the covered thick gold Au22 of the covered thick gold electrode metal structure 2b extends to connect to the metal connection layer Tb, and another end (e.g., the right end) of the covered thick gold Au22 extends to connect to the surface 11 of the ceramic substrate layer 1, but the present disclosure is not limited thereto.

Furthermore, since the bottom of the third electrode metal (e.g., the right electrode metal structure 2) does not connect to the metal connection layer Tb, the surface of the third electrode metal cannot be electroplated with thick gold, and no thick gold layer is formed on the third electrode metal. Thus, the third electrode metal can be defined as a non-thick-gold-plated electrode metal 2c.

As shown in FIG. 2C, step S207 includes stripping and removing the second pattern mask P2 from the ceramic substrate layer 1, thereby exposing the protruded thick gold electrode metal structure 2a, the covered thick gold electrode metal structure 2b, and the non-thick-gold-plated electrode metal 2c to an external environment.

A third selective plating operation is performed, which includes steps S208 to S210.

Step S208 includes forming and covering a third pattern mask P3 on the protruded thick gold electrode metal structure 2a and the covered thick gold electrode metal structure 2b, in which the third pattern mask P3 completely covers the protruded thick gold electrode metal structure 2a, and partially covers the covered thick gold electrode metal structure 2b while leaving the thick gold layer Au2 (i.e., the covered thick gold Au22) of the covered thick gold electrode metal structure 2b at least partially exposed through a third selective plating area A3 defined by the third pattern mask P3, thus defining a bonding metal layer plating area (i.e., A3) on the thick gold layer Au2.

The material of the third pattern mask P3 can be similar to that of the first pattern mask P1 or the second pattern mask P2, and will not be further detailed here.

Step S209 includes forming a bonding metal layer BL protruding on the thick gold layer Au2 (i.e., the covered thick gold Au22) of the covered thick gold electrode metal structure 2b through electroplating or physical vapor deposition, based on a third selective plating area A3 of the third pattern mask P3.

In some embodiments of the present disclosure, the material of the bonding metal layer BL can be, for example, at least one of platinum and gold-tin (AuSn) alloy. Further, a width of the bonding metal layer BL is smaller than a width of the covered thick gold electrode metal structure 2b, but the present disclosure is not limited thereto.

As shown in FIG. 2D, step S210 includes stripping and removing the third pattern mask P3 from the ceramic substrate layer 1, thereby exposing the protruded thick gold electrode metal structure 2a, the covered thick gold electrode metal structure 2b, and the non-thick-gold-plated electrode metal 2c to the external environment once again, thus completing the preparation of the metallized ceramic substrate E2 of the second embodiment.

Accordingly, the metallized ceramic substrate E2 of the present embodiment includes at least one protruded thick gold electrode metal structure 2a, at least one covered thick gold electrode metal structure 2b, and at least one non-thick-gold-plated electrode metal 2c, which are independently disposed on the ceramic substrate layer 1, in which a bonding metal layer BL is formed and protrudes on the thick gold layer Au2 (i.e., the covered thick gold Au22) of the covered thick gold electrode metal structure 2b.

Furthermore, the thickness of the protruded thick gold Au21 of the protruded thick gold electrode metal structure 2a is greater than the thickness of the thin gold layer Au1, and the thickness of the covered thick gold Au22 of the covered thick gold electrode metal structure 2b is greater than the thickness of the thin gold layer Au1.

### Third Embodiment

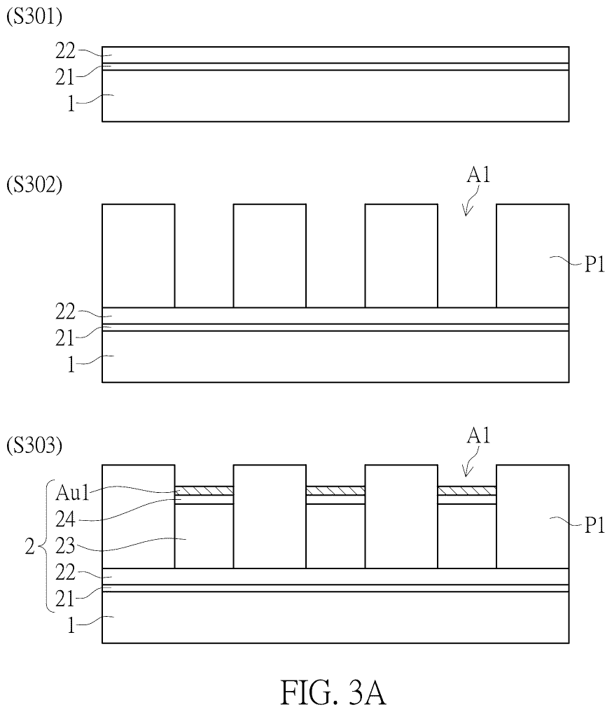

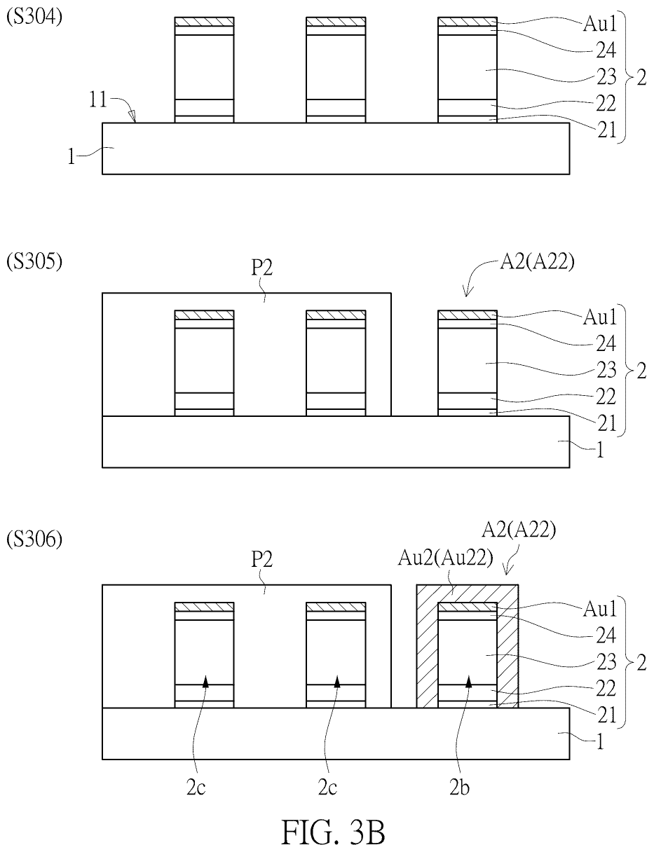

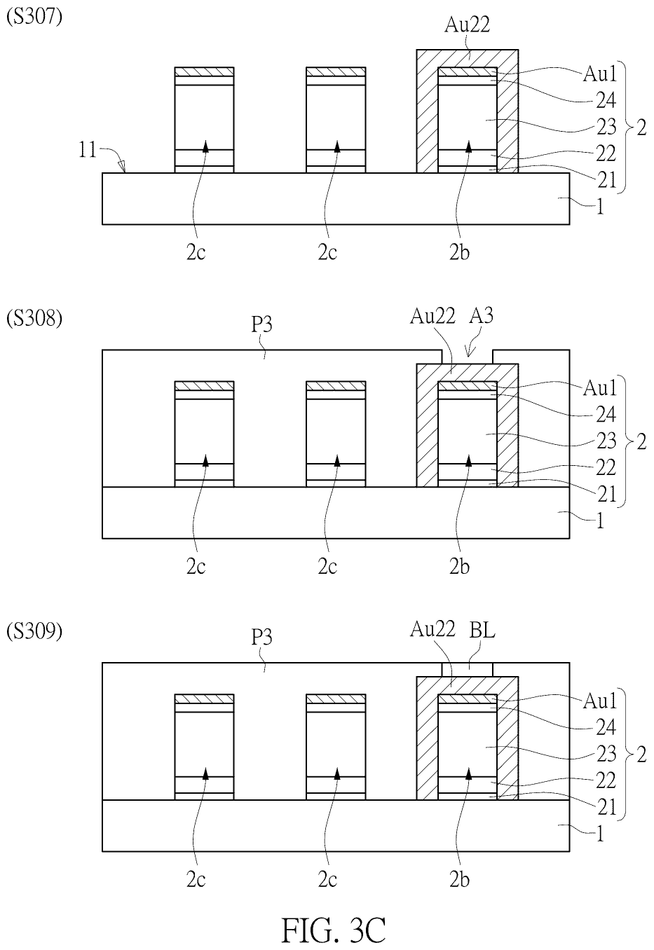

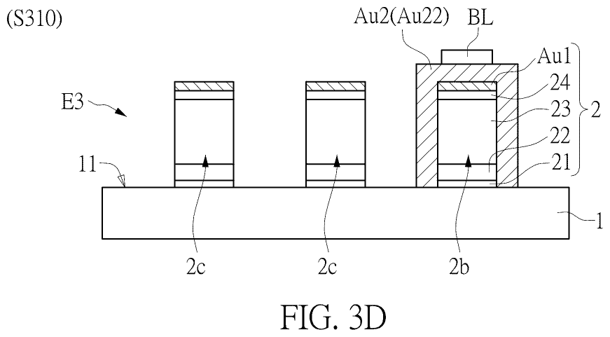

Referring to FIGS. 3A to 3D, the manufacturing method of the metallized ceramic substrate E3 according to the third embodiment of the present disclosure includes steps S301 to S310.

As shown in FIG. 3A, step S301 includes providing a ceramic substrate layer 1, and sequentially forming a first metal layer 21 (sputtered titanium layer) and a second metal layer 22 (sputtered copper layer) on a surface 11 of the ceramic substrate layer 1.

A first selective plating operation is performed, which includes steps S302 to S304.

Step S302 includes forming a first pattern mask P1 on the ceramic substrate layer 1, in which the first pattern mask P1 defines a first selective plating area A1, and the first selective plating area A1 at least partially exposes the surface of the second metal layer 22 (sputtered copper layer).

Step S303 includes sequentially forming a third metal layer 23 (electroplated copper layer), a fourth metal layer 24 (electroplated nickel layer), and a thin gold layer Au1 on an exposed copper surface of the second metal layer 22 (sputtered copper layer) through electroplating, based on the first selective plating area A1 of the first pattern mask P1, thereby forming at least one electrode metal structure 2 protruding on the surface 11 of the ceramic substrate layer 1. In the present embodiment, the quantity of the electrode metal structure 2 is plural as shown in FIG. 3A, where there are three electrode metal structures 2 (left, middle, and right electrode metal structures 2), but the present disclosure is not limited thereto.

As shown in FIG. 3B, step S304 includes stripping and removing the first pattern mask P1 from the ceramic substrate layer 1, and etching and removing the exposed portions of the first metal layer 21 (sputtered titanium layer) and the second metal layer 22 (sputtered copper layer), thereby exposing the surface 11 of the ceramic substrate layer 1, and electrically insulating the plurality of electrode metal structures 2 from each other.

A second selective plating operation is performed, which includes steps S305 to S307.

Step S305 includes forming a second pattern mask P2 on the ceramic substrate layer 1, in which the second pattern mask P2 defines a second selective plating area A2, which includes a covered thick gold plating area A22 corresponding to at least one of the electrode metal structures 2 (e.g., the rightmost electrode metal structure 2 in FIG. 3B) to fully expose the sidewalls and surface of the thin gold layer Au1 of the rightmost electrode metal structure 2. Further, the second pattern mask P2 fully covers at least another one of the electrode metal structures 2 (e.g., the left and middle electrode metal structures 2 in FIG. 3B).

Step S306 includes forming a covered thick gold Au22 on an exterior of the electrode metal structure 2 corresponding to the covered thick gold plating area A22 through electro-less plating, based on the second selective plating area A2 of the second pattern mask P2, and the covered thick gold Au22 covers the top surface and sidewalls of the electrode metal structure 2, thus defining a covered thick gold electrode metal structure 2b.

Additionally, the other electrode metal structures 2 that are fully covered by the second pattern mask P2 are not plated with thick gold, thus defining at least one non-thick-gold-plated electrode metal 2c.

As shown in FIG. 3C, step S307 includes stripping and removing the second pattern mask P2 from the ceramic substrate layer 1, thereby exposing the covered thick gold electrode metal structure 2b and the non-thick-gold-plated electrode metals 2c to the external environment.

A third selective plating operation is performed, which includes steps S308 to S310.

Step S308 includes forming and covering a third pattern mask P3 on the covered thick gold electrode metal structure 2b and the non-thick-gold-plated electrode metals 2c.

The third pattern mask P3 completely covers the non-thick-gold-plated electrode metals 2c, and partially covers the covered thick gold electrode metal structure 2b while leaving the covered thick gold Au22 of the covered thick gold electrode metal structure 2b at least partially exposed through a third selective plating area A3 defined by the third pattern mask P3, thus defining a bonding metal layer plating area (i.e., A3) on the top surface of the covered thick gold Au22.

Step S309 includes forming a bonding metal layer BL protruding on the thick gold layer Au2 (covered thick gold Au22) of the covered thick gold electrode metal structure 2b through physical vapor deposition, based on the third selective plating area A3 of the third pattern mask P3. The material of the bonding metal layer BL can be, for example, at least one of platinum and gold-tin (AuSn) alloy.

As shown in FIG. 3D, step S310 includes stripping and removing the third pattern mask P3 from the ceramic substrate layer 1, thereby exposing the covered thick gold electrode metal structure 2b and the non-thick-gold-plated electrode metals 2c once again, thus completing the preparation of the metallized ceramic substrate E3 of the third embodiment.

The metallized ceramic substrate E3 of the present embodiment includes at least one covered thick gold electrode metal structure 2b and at least one non-thick-gold-plated electrode metal 2c, which are independently disposed on the ceramic substrate layer 1, in which a bonding metal layer BL is formed and protrudes on the thick gold layer Au2 (covered thick gold Au22) of the covered thick gold electrode metal structure 2b.

### Fourth Embodiment

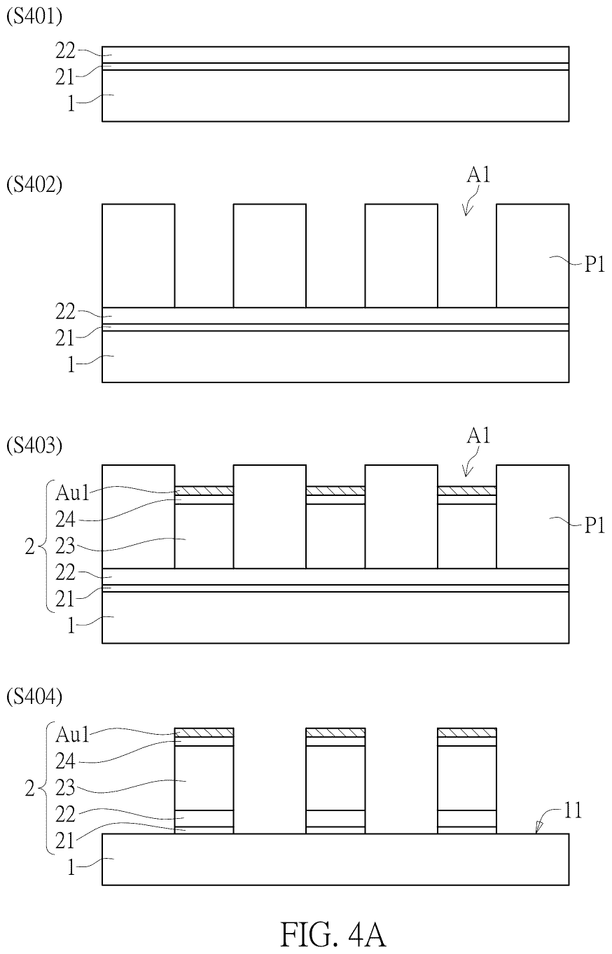

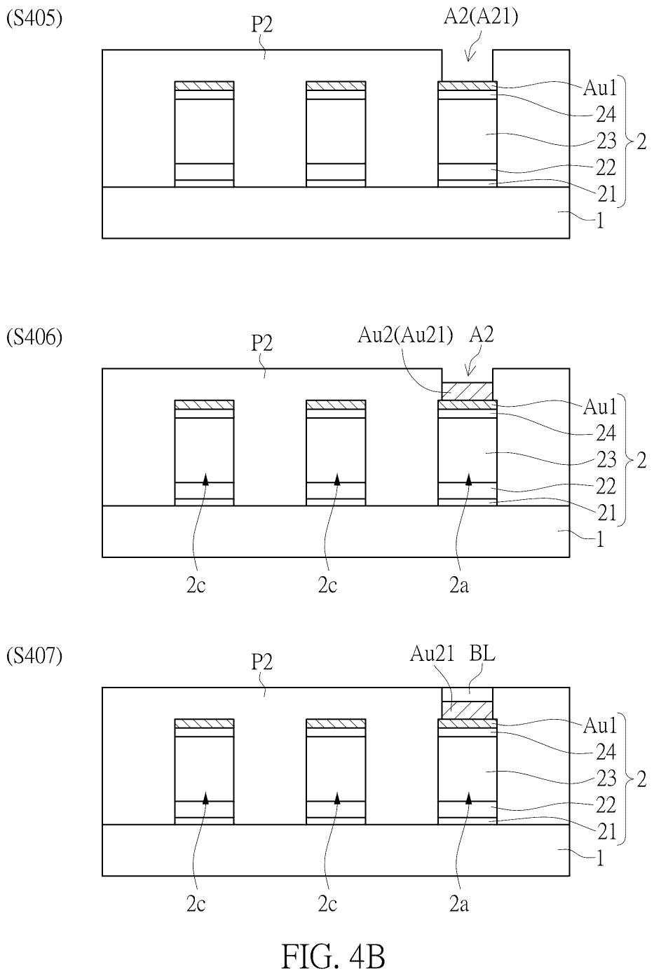

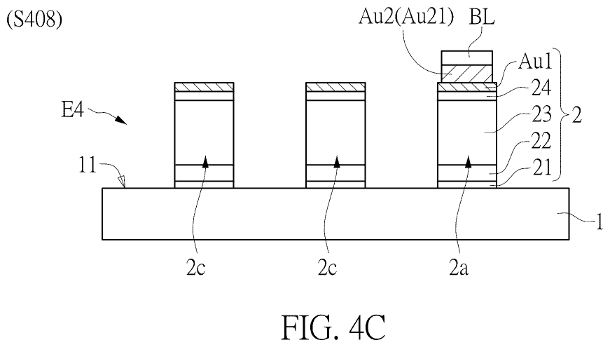

Referring to FIGS. 4A to 4C, the manufacturing method of the metallized ceramic substrate E4 of the fourth embodiment of the present disclosure includes steps S401 to S408.

As shown in FIG. 4A, step S401 includes providing a ceramic substrate layer 1, and sequentially forming a first metal layer 21 (sputtered titanium layer) and a second metal layer 22 (sputtered copper layer) on a surface 11 of the ceramic substrate layer 1.

A first selective plating operation is performed, which includes steps S402 to S404.

Step S402 includes forming a first pattern mask P1 on the ceramic substrate layer 1, in which the first pattern mask P1 defines a first selective plating area A1, and the first selective plating area A1 at least partially exposes the surface of the second metal layer 22 (sputtered copper layer).

Step S403 includes sequentially forming a third metal layer 23 (electroplated copper layer), a fourth metal layer 24 (electroplated nickel layer), and a thin gold layer Au1 on an exposed copper surface of the second metal layer 22 (sputtered copper layer) through electroplating, based on the first selective plating area A1 of the first pattern mask P1, thereby forming at least one electrode metal structure 2 protruding on the surface 11 of the ceramic substrate layer 1. In the present embodiment, the quantity of the electrode metal structure 2 is plural as shown in FIG. 4A, where there are three the electrode metal structures 2 (e.g., left, middle, and right electrode metal structures 2) in the present embodiment, but the present disclosure is not limited thereto.

Step S404 includes stripping and removing the first pattern mask P1 from the ceramic substrate layer 1, and selectively etching and removing the exposed portions of the first metal layer 21 (sputtered titanium layer) and the second metal layer 22 (sputtered copper layer), thereby exposing the surface 11 of the ceramic substrate layer 1, and electrically insulating the plurality of electrode metal structures 2 from each other.

A second selective plating operation is performed, which includes steps S405 to S408.

Step S405 includes forming a second pattern mask P2 on the ceramic substrate layer 1, in which the second pattern mask P2 defines a second selective plating area A2, which includes a protruded thick gold plating area A21 corresponding to at least one of the plurality of electrode metal structures 2 (e.g., the rightmost electrode metal structure 2 as shown in FIG. 4B), to partially cover and partially expose the top surface of the thin gold layer Au1 of that electrode metal structure 2.

Furthermore, the second pattern mask P2 fully covers at least another one of the electrode metal structures 2 (e.g., the left and middle electrode metal structures 2 in FIG. 4B).

Step S406 includes forming a protruded thick gold Au21 on the thin gold layer Au1 corresponding to the protruded thick gold plating area A21 through electro-less plating, based on the second selective plating area A2 of the second pattern mask P2, thus defining a protruded thick gold electrode metal structure 2a.

Additionally, at least another one of the electrode metal structures 2 that is fully covered by the second pattern mask P2 is not plated with thick gold, thus defining at least one non-thick-gold-plated electrode metal 2c.

It is worth noting that in the present embodiment, the top surface of the protruded thick gold Au21 is lower than the top surface of the second pattern mask P2, thereby leaving a bonding metal layer plating area in the second selective plating area A2.

Step S407 includes forming a bonding metal layer BL on the thick gold layer Au2 (protruded thick gold Au21) of the protruded thick gold electrode metal structure 2a through physical vapor deposition, based on the bonding metal layer plating area reserved in the second selective plating area A2.

In the present embodiment, the width of the bonding metal layer BL is approximately equal to the width of the protruded thick gold Au21, but smaller than the width of the thin gold layer Au1, but the present disclosure is not limited thereto.

As shown in FIG. 4C, step S408 includes stripping and removing the second pattern mask P2 from the ceramic substrate layer 1, thereby exposing the protruded thick gold electrode metal structure 2a and the non-thick-gold-plated electrode metals 2c, thus completing the preparation of the metallized ceramic substrate E4 of the fourth embodiment.

Accordingly, the metallized ceramic substrate E4 of the present embodiment includes at least one protruded thick gold electrode metal structure 2a and at least one non-thick-gold-plated electrode metal 2c, which are independently disposed on the ceramic substrate layer 1.

### Fifth Embodiment

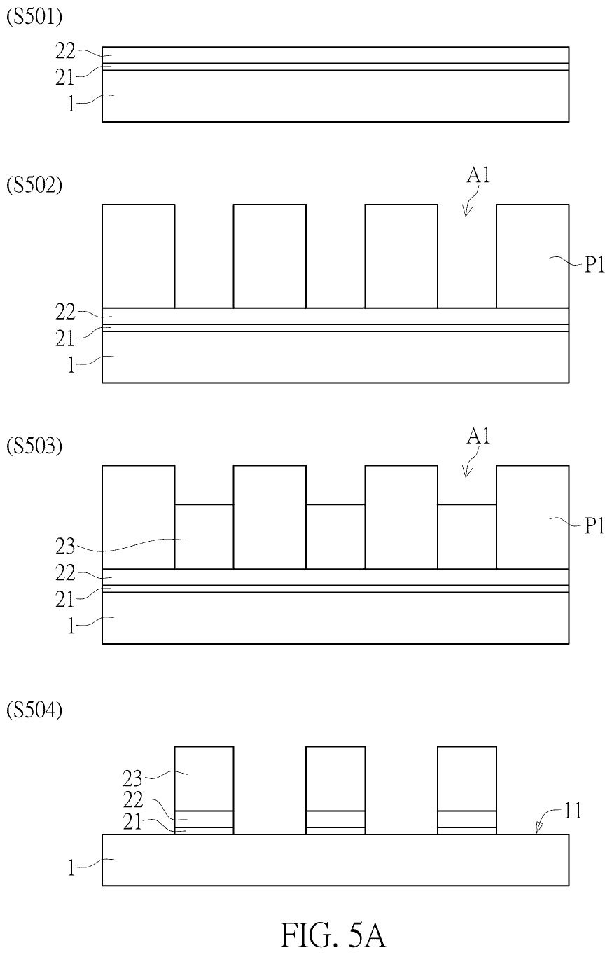

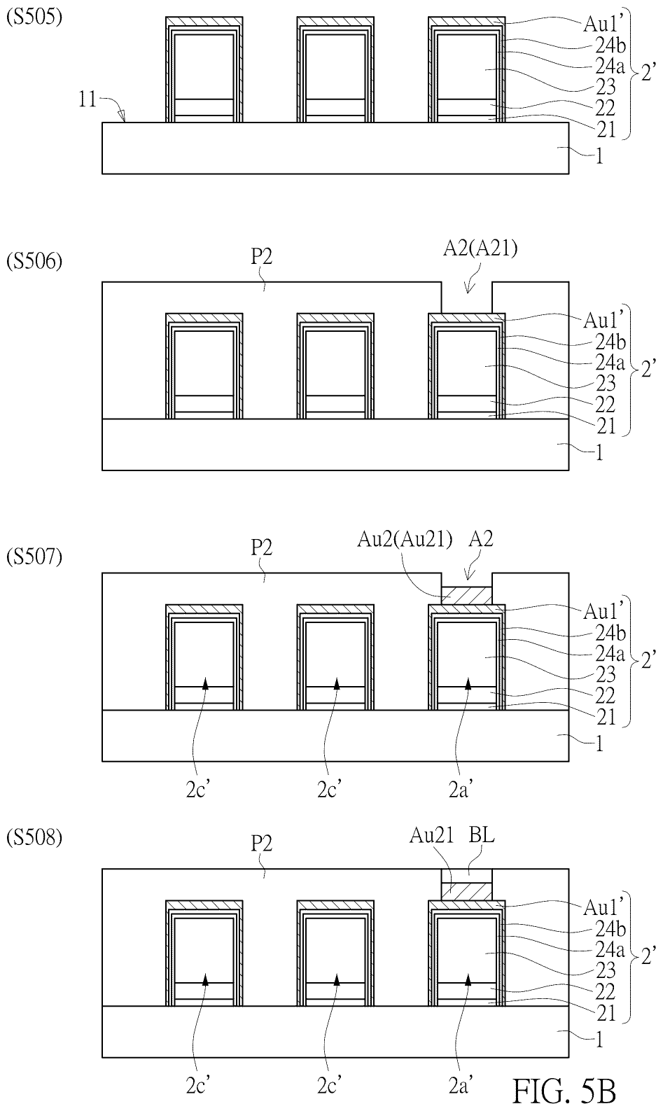

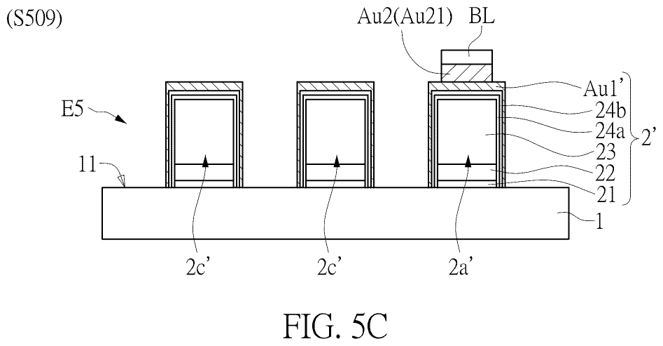

Referring to FIGS. 5A to 5C, the manufacturing method of the metallized ceramic substrate E5 of the fifth embodiment of the present disclosure includes steps S501 to S509.

As shown in FIG. 5A, step S501 includes providing a ceramic substrate layer 1, and sequentially forming a first metal layer 21 (sputtered titanium layer) and a second metal layer 22 (sputtered copper layer) on a surface 11 of the ceramic substrate layer 1.

A first selective plating operation is performed, which includes steps S502 to S505.

Step S502 includes forming a first pattern mask P1 on the ceramic substrate layer 1, in which the first pattern mask P1 defines a first selective plating area A1, and the first selective plating area A1 at least partially exposes the surface of the second metal layer 22 (sputtered copper layer).

Step S503 includes forming a third metal layer 23 (electroplated copper layer) on the exposed copper surface of the second metal layer 22 (sputtered copper layer) through electroplating, based on the first selective plating area A1 of the first pattern mask P1.

Step S504 includes stripping and removing the first pattern mask P1 from the ceramic substrate layer 1, and selectively etching and removing the exposed portions of the first metal layer 21 (sputtered titanium layer) and the second metal layer 22 (sputtered copper layer), thereby exposing the surface 11 of the ceramic substrate layer 1, and forming at least one metal pillar (not labeled in the figure) composed of a stacked structure including the first metal layer 21 (sputtered titanium layer), the second metal layer 22 (sputtered copper layer), and the third metal layer 23 (electroplated copper layer), independently disposed on the surface 11 of the ceramic substrate layer 1. In the present embodiment, the quantity of metal pillars is plural as shown in FIG. 5A, where there are three metal pillars (e.g., left, middle, and right metal pillars), but the present disclosure is not limited thereto.

As shown in FIG. 5B, step S505 includes forming a precious metal covering layer (e.g., 24a, 24b, Au1′) covering around the exterior of the at least one metal pillar through electro-less plating, thereby forming at least one electrode metal structure 2′. The precious metal covering layer can be a single-layer or multi-layer structure, and the outermost layer of the precious metal covering layer is a thin gold layer Au1′, away from the metal pillar.

In the present embodiment, the precious metal covering layer is a multi-layer covering structure, sequentially including a first covering layer 24a, a second covering layer 24b, and a thin gold layer Au1′ from the inner side to the outer side thereof.

That is, the first covering layer 24a covers the exterior of the metal pillar, the second covering layer 24b covers the exterior of the first covering layer 24a, and the thin gold layer Au1′ covers the exterior of the second covering layer 24b, forming the outermost layer of the multi-layer covering structure.

The first covering layer 24a is a nickel layer (Ni layer) formed through electro-less plating, the second covering layer 24b is a palladium layer (Pd layer) formed through electro-less plating, and the thin gold layer Au1′ is a thin gold covering layer formed through electro-less plating, but the present disclosure is not limited thereto.

That is, the at least one electrode metal structure 2′ includes a metal pillar formed on the surface 11 of the ceramic substrate layer 1, and the metal pillar is formed by the stacked structure of the first metal layer 21 (sputtered titanium layer), the second metal layer 22 (sputtered copper layer), and the third metal layer 23 (electroplated copper layer), and the at least one electrode metal structure 2′ further includes a first covering layer 24a (electro-less nickel layer), a second covering layer 24b (electro-less palladium layer), and a thin gold layer Au1′ (electro-less thin gold covering layer) sequentially covering the exterior of the metal pillar, but the present disclosure is not limited thereto.

In the present embodiment, the quantity of the electrode metal structures 2′ is plural as shown in FIG. 5B, which shows three electrode metal structures 2′ (e.g., left, middle, and right electrode metal structures 2′), but the present disclosure is not limited thereto.

A second selective plating operation is performed, which includes steps S506 to S509.

Step S506 includes forming a second pattern mask P2 on the ceramic substrate layer 1, in which the second pattern mask P2 defines a second selective plating area A2, which includes a protruded thick gold plating area A21 corresponding to at least one of the plurality of electrode metal structures 2′ (e.g., the rightmost electrode metal structure 2′ as shown in FIG. 5B), to partially cover and partially expose the top surface of the thin gold layer Au1′ (electro-less thin gold covering layer) of that electrode metal structure 2′. Further, the second pattern mask P2 fully covers at least another one of the electrode metal structures 2′ (e.g., the left and middle electrode metal structures 2′ in FIG. 5B).

Step S507 includes forming a protruded thick gold Au21 on the thin gold layer Au1′ corresponding to the protruded thick gold plating area A21 through electro-less plating, based on the second selective plating area A2 of the second pattern mask P2, thereby defining a protruded thick gold electrode metal structure 2a′.

Additionally, at least another one of the electrode metal structures 2′ that is fully covered by the second pattern mask P2 is not plated with thick gold, thereby defining at least one non-thick-gold-plated electrode metal 2c′.

In the present embodiment, the top surface of the protruded thick gold Au21 is lower than the top surface of the second pattern mask P2, leaving a bonding metal layer plating area.

Step S508 includes forming a bonding metal layer BL on the thick gold layer Au2 (protruded thick gold Au21) of the protruded thick gold electrode metal structure 2a′ through physical vapor deposition or electro-less plating, based on the bonding metal layer plating area reserved in the second selective plating area A2.

As shown in FIG. 5C, step S509 includes stripping and removing the second pattern mask P2 from the ceramic substrate layer 1, thereby exposing the protruded thick gold electrode metal structure 2a′ and the non-thick-gold-plated electrode metals 2c′, thus completing the preparation of the metallized ceramic substrate E5 of the fifth embodiment.

### Sixth Embodiment

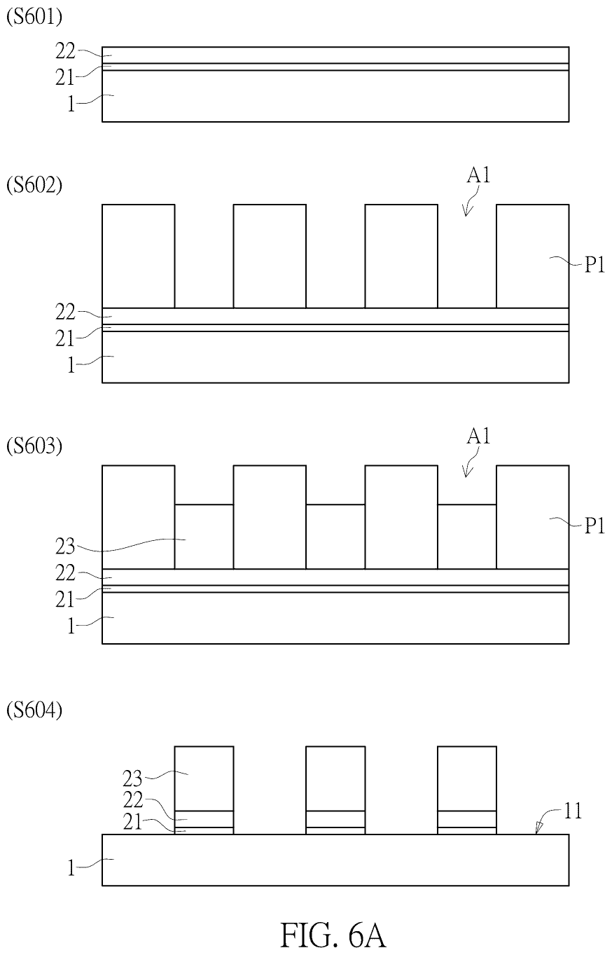

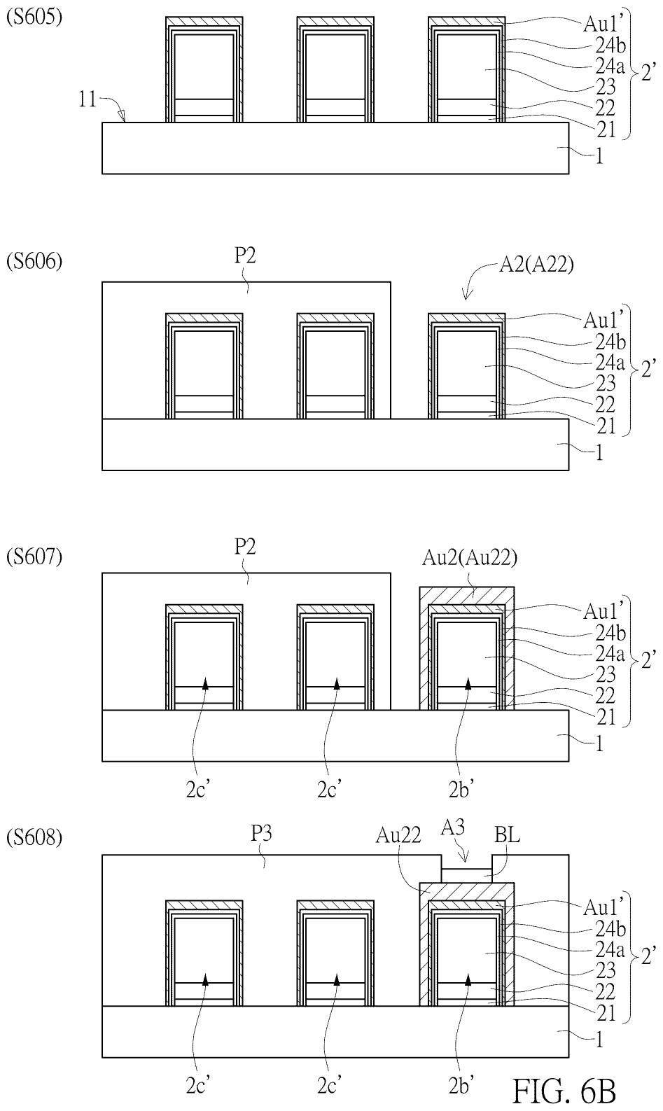

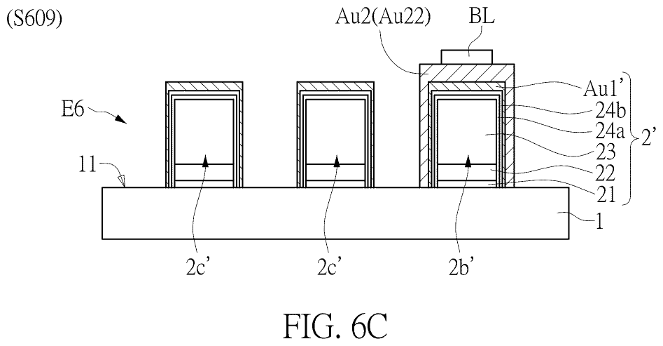

Referring to FIGS. 6A to 6C, the manufacturing method of the metallized ceramic substrate E6 of the sixth embodiment of the present disclosure includes steps S601 to S609.

As shown in FIG. 6A, step S601 includes providing a ceramic substrate layer 1, and sequentially forming a first metal layer 21 (sputtered titanium layer) and a second metal layer 22 (sputtered copper layer) on a surface 11 of the ceramic substrate layer 1.

A first selective plating operation is performed, which includes steps S602 to S605.

Step S602 includes forming a first pattern mask P1 on the ceramic substrate layer 1, in which the first pattern mask P1 defines a first selective plating area A1, and the first selective plating area A1 at least partially exposes the surface of the second metal layer 22 (sputtered copper layer).

Step S603 includes forming a third metal layer 23 (electroplated copper layer) on an exposed copper surface of the second metal layer 22 (sputtered copper layer) through electroplating, based on the first selective plating area A1 of the first pattern mask P1.

Step S604 includes stripping and removing the first pattern mask P1 from the ceramic substrate layer 1, and selectively etching and removing the exposed portions of the first metal layer 21 (sputtered titanium layer) and the second metal layer 22 (sputtered copper layer), thereby exposing the surface 11 of the ceramic substrate layer 1, and forming at least one metal pillar composed of a stacked structure including the first metal layer 21 (sputtered titanium layer), the second metal layer 22 (sputtered copper layer), and the third metal layer 23 (electroplated copper layer), independently disposed on the surface 11 of the ceramic substrate layer 1. In the present embodiment, the quantity of metal pillars is plural.

As shown in FIG. 6B, step S605 includes forming a precious metal covering layer (such as 24a, 24b, Au1′) around the exterior of at least one metal pillar through electro-less plating, thereby forming at least one electrode metal structure 2′. The precious metal covering layer can be a single-layer or multi-layer structure, and the outermost layer of the precious metal covering layer is a thin gold layer Au1′, away from the metal pillar.

In the present embodiment, the precious metal covering layer is a multi-layer covering structure, sequentially including a first covering layer 24a (electro-less nickel layer), a second covering layer 24b (electro-less palladium layer), and a thin gold layer Au1′ (electro-less thin gold covering layer), but the present disclosure is not limited thereto.

That is, the at least one electrode metal structure 2′ includes a metal pillar, formed by a stacked structure composed of the first metal layer 21 (sputtered titanium layer), the second metal layer 22 (sputtered copper layer), and the third metal layer 23 (electroplated copper layer), which are formed on the surface 11 of the ceramic substrate layer 1. The at least one electrode metal structure 2′ further includes a first covering layer 24a (electro-less nickel layer), a second covering layer 24b (electro-less palladium layer), and a thin gold layer Au1′ (electro-less thin gold covering layer) sequentially covering the exterior of the metal pillar, but the present disclosure is not limited thereto.

A second selective plating operation is performed, which includes steps S606 to S607.

Step S606 includes forming a second pattern mask P2 on the ceramic substrate layer 1, in which the second pattern mask P2 defines a second selective plating area A2, which includes a covered thick gold plating area A22 corresponding to at least one of the plurality of electrode metal structures 2′ (e.g., the rightmost electrode metal structure 2′ in FIG. 6B), to fully expose the sidewalls and surface of the thin gold layer Au1′ (electro-less thin gold covering layer) of that electrode metal structure 2′. Further, the second pattern mask P2 fully covers at least another one of the electrode metal structures 2′ (e.g., the left and middle electrode metal structures 2′ in FIG. 6B).

Step S607 includes forming a covered thick gold Au22 covering on an exterior of the thin gold layer Au1′ (electro-less thin gold covering layer) of the electrode metal structure 2′ corresponding to the covered thick gold plating area A22 through electro-less plating, based on the second selective plating area A2 of the second pattern mask P2, thereby defining a covered thick gold electrode metal structure 2b′. In the present embodiment, the covered thick gold Au22 and the thin gold layer Au1′ (electro-less thin gold covering layer) form a dual-layer gold covering structure. The thickness of the covered thick gold Au22 is greater than that of the thin gold layer Au1′.

Additionally, at least another one of the electrode metal structures 2′ that is fully covered by the second pattern mask P2 are not plated with thick gold, thereby defining at least one non-thick-gold-plated electrode metal 2c′.

Subsequently, the second pattern mask P2 can be selectively removed, but the present disclosure is not limited thereto.

A third selective plating operation is performed, which includes steps S608 to S609.

Step S608 includes forming and covering a third pattern mask P3 on the covered thick gold electrode metal structure 2b′ and the non-thick-gold-plated electrode metals 2c′, in which the third pattern mask P3 completely covers the non-thick-gold-plated electrode metals 2c′, and partially covers the covered thick gold electrode metal structure 2b′, leaving the covered thick gold Au22 of the covered thick gold electrode metal structure 2b′ at least partially exposed through a third selective plating area A3 defined by the third pattern mask P3, thereby defining a bonding metal layer plating area on the covered thick gold Au22 (i.e., A3).

Step S608 further includes forming a bonding metal layer BL protruding on the thick gold layer Au2 (covered thick gold Au22) of the covered thick gold electrode metal structure 2b′ through electro-less plating or physical vapor deposition, based on the third selective plating area A3 of the third pattern mask P3. The material of the bonding metal layer BL can be, for example, at least one of platinum and gold-tin (AuSn) alloy.

As shown in FIG. 6C, step S609 includes stripping and removing the third pattern mask P3 from the ceramic substrate layer 1, thereby exposing the covered thick gold electrode metal structure 2b′ and the non-thick-gold-plated electrode metals 2c′, thus completing the preparation of the metallized ceramic substrate E6 of the sixth embodiment. The metallized ceramic substrate E6 of the present embodiment includes at least one covered thick gold electrode metal structure 2b′ and at least one non-thick-gold-plated electrode metal 2c′, which are independently disposed on the ceramic substrate layer 1, in which a protruded bonding metal layer BL is formed on the thick gold layer Au2 (covered thick gold Au22) of the covered thick gold electrode metal structure 2b′.

### Seventh Embodiment

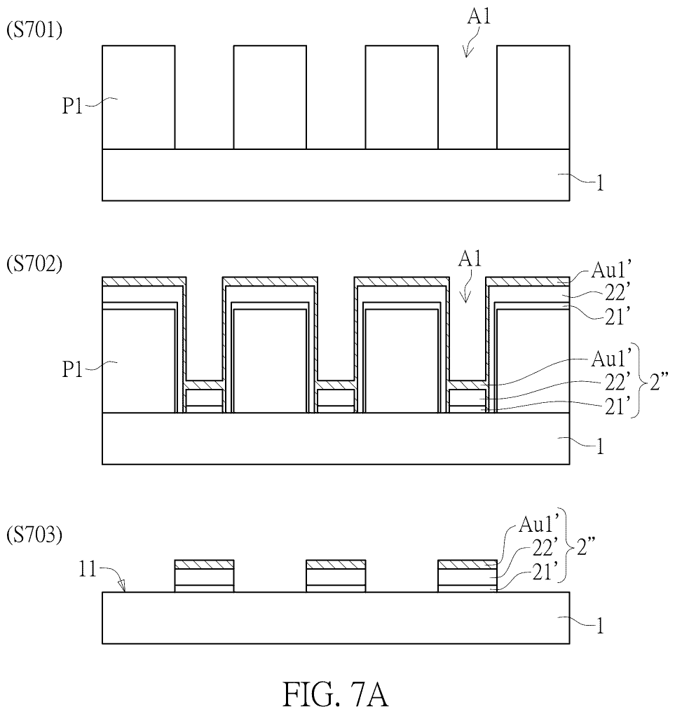

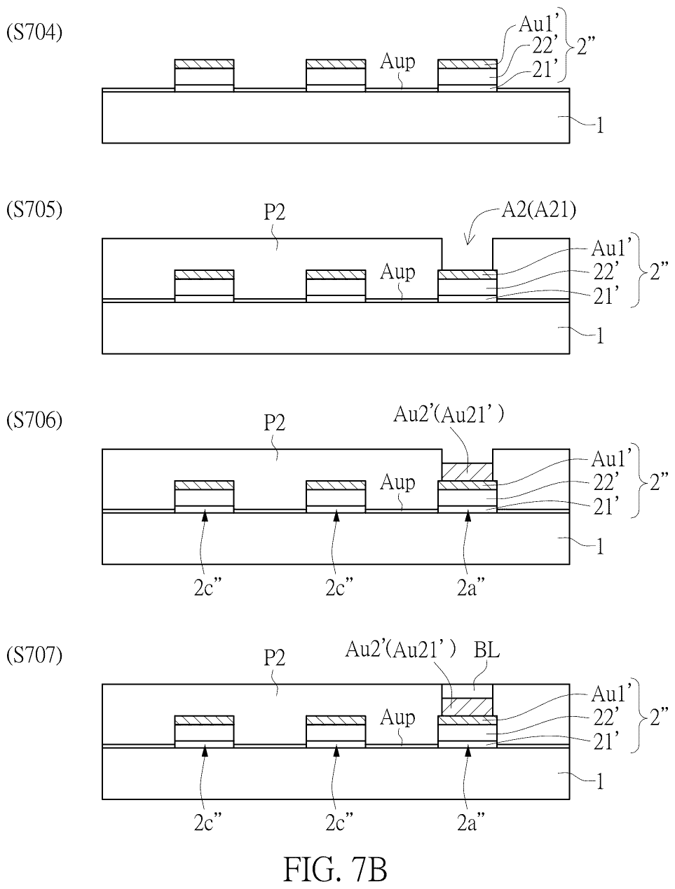

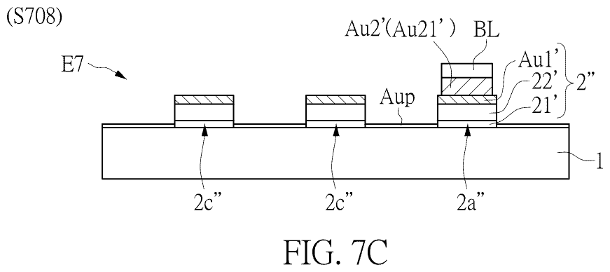

Referring to FIGS. 7A to 7C, the manufacturing method of the metallized ceramic substrate E7 of the seventh embodiment of the present disclosure includes steps S701 to S708.

A first selective plating operation is performed, which includes steps S701 to S704.

As shown in FIG. 7A, step S701 includes providing a ceramic substrate layer 1, and forming a first pattern mask P1 on the ceramic substrate layer 1, in which the first pattern mask P1 defines a first selective plating area A1, and the first selective plating area A1 at least partially exposes the surface 11 of the ceramic substrate layer 1.

Step S702 includes sequentially forming a first metal layer 21′, a second metal layer 22′, and a thin gold layer Au1′ on an exposed surface 11 of the ceramic substrate layer 1 through evaporation, sputtering, or physical vapor deposition (PVD), based on the first selective plating area A1 of the first pattern mask P1. The first metal layer 21′ can be, for example, a titanium layer (Ti layer), and the second metal layer 22′ can be, for example, a platinum layer (Pt layer).

That is, the first metal layer 21′, the second metal layer 22′, and the thin gold layer Au1′ are sequentially formed on the exposed surface 11 of the ceramic substrate layer 1 located in the first selective plating area A1, thereby forming at least one electrode metal structure 2″.

In the present embodiment, the first metal layer 21′, the second metal layer 22′, and the thin gold layer Au1′ also extend to cover the inner sidewalls and top surface of the first pattern mask P1 located in the first selective plating area A1, but the present disclosure is not limited thereto.

Step S703 includes removing the first pattern mask P1 (and the first metal layer 21′, the second metal layer 22′, and the thin gold layer Au1′ covering thereon) from the ceramic substrate layer 1, so that the at least one electrode metal structure 2″ is independently disposed on the surface 11 of the ceramic substrate layer 1.

In the present embodiment, the quantity of the electrode metal structures 2″ is plural as shown in FIG. 7A, which shows three electrode metal structures 2″ (e.g., left, middle, and right electrode metal structures 2″), but the present disclosure is not limited thereto.

As shown in FIG. 7B, step S704 includes further forming a thin gold connection layer Aup on the surface 11 of the ceramic substrate layer 1 through evaporation, sputtering, or physical vapor deposition (PVD), in which the thin gold connection layer Aup is connected to the bottoms of the plurality of electrode metal structures 2″, thereby electrically connecting the plurality of electrode metal structures 2″ together. The thin gold connection layer Aup can serve as a seed layer to facilitate subsequent electroplating operations.

A second selective plating operation is performed, which includes steps S705 to S708.

Step S705 includes forming a second pattern mask P2 on the ceramic substrate layer 1, in which the second pattern mask P2 defines a second selective plating area A2, which includes a protruded thick gold plating area A21 corresponding to at least one of the plurality of electrode metal structures 2″ e.g., the rightmost electrode metal structure 2″ in FIG. 7B), to partially cover and partially expose the top surface of the thin gold layer Au1′ of that electrode metal structure 2″. Further, the second pattern mask P2 fully covers at least another one of the electrode metal structures 2″ (e.g., the left and middle electrode metal structures 2″ as shown in FIG. 7B).

Step S706 includes forming a protruded thick gold Au21′ on the top surface of the thin gold layer Au1′ corresponding to the protruded thick gold plating area A21 through electroplating via the thin gold connection layer Aup, based on the second selective plating area A2 of the second pattern mask P2, thereby defining a protruded thick gold electrode metal structure 2a″.

Additionally, at least another one of the electrode metal structures 2″ that is fully covered by the second pattern mask P2 is not plated with thick gold, thereby defining at least one non-thick-gold-plated electrode metal 2c″.

In the present embodiment, the top surface of the protruded thick gold Au21′ is lower than the top surface of the second pattern mask P2, leaving a bonding metal layer plating area in the second selective plating area A2.

Step S707 includes forming a bonding metal layer BL on the protruded thick gold Au21′ of the protruded thick gold electrode metal structure 2a″ through physical vapor deposition or electroplating, based on the bonding metal layer plating area reserved in the second selective plating area A2.

In the present embodiment, the width of the bonding metal layer BL is approximately equal to the width of the protruded thick gold Au21′, but smaller than the width of the thin gold layer Au1′, but the present disclosure is not limited thereto.

As shown in FIG. 7C, step S708 includes stripping and removing the second pattern mask P2 from the ceramic substrate layer 1, thereby exposing the protruded thick gold electrode metal structure 2a″ and the non-thick-gold-plated electrode metals 2c″, thus completing the preparation of the metallized ceramic substrate E7 of the seventh embodiment.

The bottoms of the protruded thick gold electrode metal structure 2a″ and the non-thick-gold-plated electrode metals 2c″ are connected to the thin gold connection layer Aup, but the present disclosure is not limited thereto. The thin gold connection layer Aup can also be removed through etching, thereby electrically isolating the protruded thick gold electrode metal structure 2a″ from the non-thick-gold-plated electrode metals 2c″.

### Eighth Embodiment

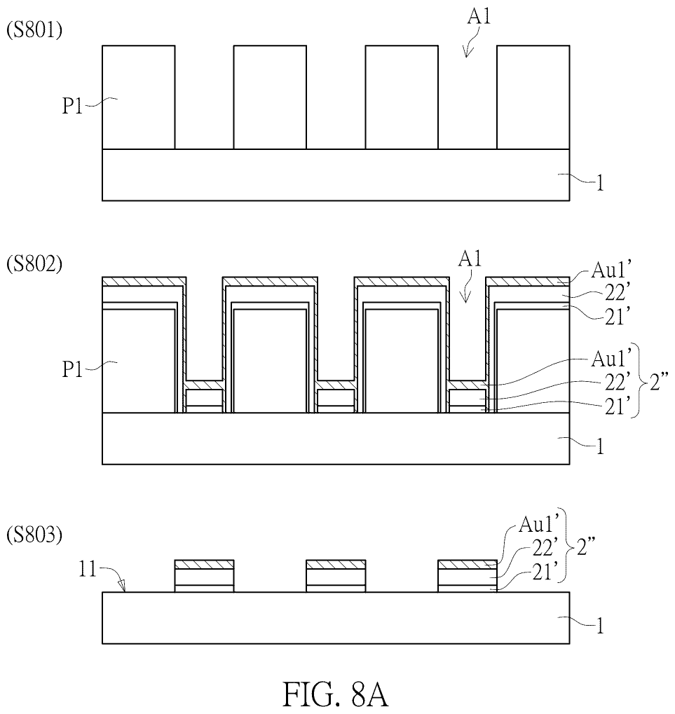

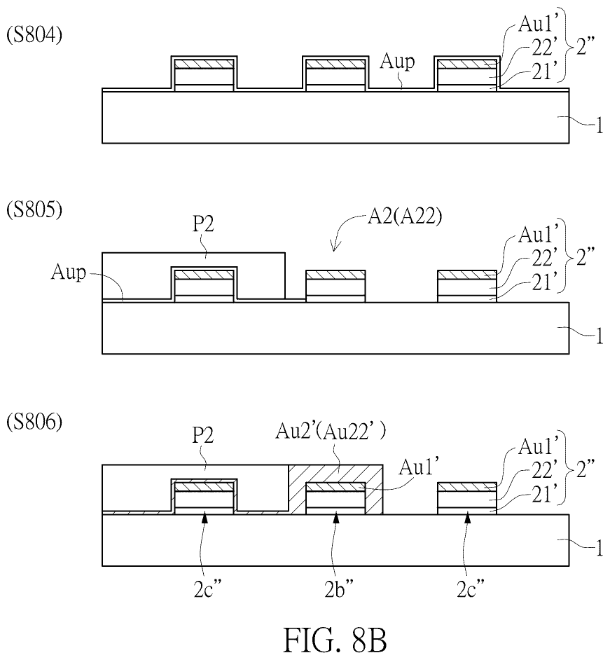

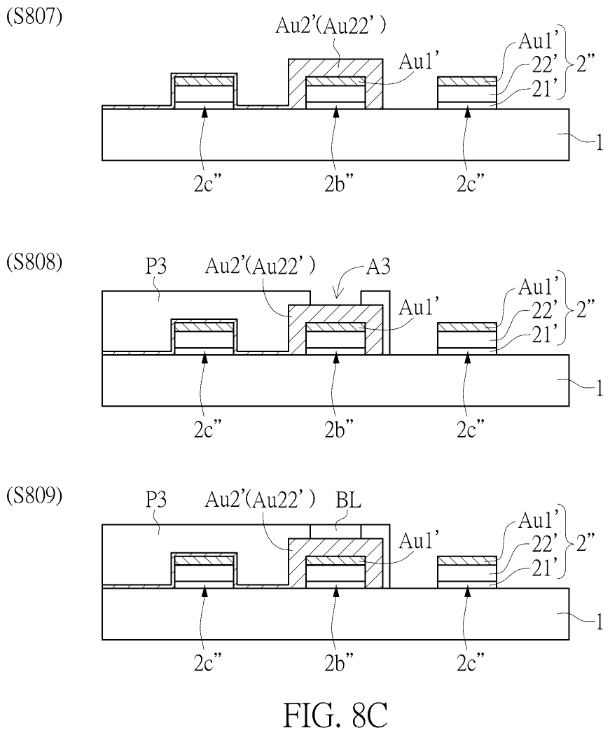

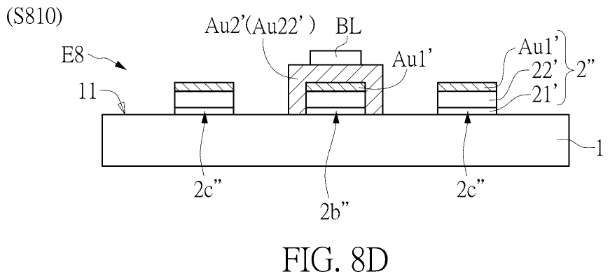

Referring to FIGS. 8A to 8D, the manufacturing method of the metallized ceramic substrate E8 of the eighth embodiment of the present disclosure includes the following steps of S801 to S810.

A first selective plating operation is performed, which includes steps S801 to S804.

As shown in FIG. 8A, step S801 includes providing a ceramic substrate layer 1 and forming a first pattern mask P1 on the ceramic substrate layer 1, in which the first pattern mask P1 defines a first selective plating area A1, and the first selective plating area A1 at least partially exposes a surface 11 of the ceramic substrate layer 1.

Step S802 includes sequentially forming a first metal layer 21′ (e.g., a titanium layer), a second metal layer 22′ (e.g., a platinum layer), and a thin gold layer Au1′ on an exposed surface 11 of the ceramic substrate layer 1 through evaporation, sputtering, or physical vapor deposition (PVD), based on the first selective plating area A1 of the first pattern mask P1, to form at least one electrode metal structure 2″ on the exposed surface 11 of the ceramic substrate layer 1 located in the first selective plating area A1.

Similar to the seventh embodiment described above, in the present embodiment, the first metal layer 21′, the second metal layer 22′, and the thin gold layer Au1′ also extend to cover the inner sidewalls and top surface of the first pattern mask P1 located in the first selective plating area A1, but the present disclosure is not limited thereto.

Step S803 includes removing the first pattern mask P1 (and the first metal layer 21′, the second metal layer 22′, and the thin gold layer Au1′ covering thereon) from the ceramic substrate layer 1, so that the at least one electrode metal structure 2″ is independently disposed on the surface 11 of the ceramic substrate layer 1.

In the present embodiment, the quantity of the electrode metal structures 2″ is plural as shown in FIG. 8A, which shows three electrode metal structures 2″ (e.g., left, middle, and right electrode metal structures 2″), but the present disclosure is not limited thereto.

As shown in FIG. 8B, step S804 includes further forming a thin gold connection layer Aup on the surface 11 of the ceramic substrate layer 1 through evaporation, sputtering, or physical vapor deposition (PVD), in which the thin gold connection layer Aup is connected to the bottoms of the plurality of electrode metal structures 2″, so as to electrically connect the plurality of electrode metal structures 2″ together, facilitating subsequent electroplating operations.

A second selective plating operation is performed, which includes steps S805 to S807.

Step S805 includes forming a second pattern mask P2 on the ceramic substrate layer 1, in which the second pattern mask P2 defines a second selective plating area A2, which includes a covered thick gold plating area A22 corresponding to at least one of the plurality of electrode metal structures 2″ (e.g., the middle electrode metal structure 2″ in FIG. 8B), to fully expose the sidewalls and surface of the thin gold layer Au1′ of that electrode metal structure 2″. Further, the second pattern mask P2 fully covers at least another one of the electrode metal structures 2″ (e.g., the left electrode metal structure 2″ in FIG. 8B).

Additionally, in the present embodiment, the thin gold connection layer Aup connects at least two of the plurality of electrode metal structures 2″ (e.g., the left electrode metal structure 2″ covered by the second pattern mask P2 and the middle electrode metal structure 2″ corresponding to the covered thick gold plating area A22 in FIG. 8B).

Further, step S805 includes partially etching away the thin gold connection layer Aup to partially expose the surface 11 of the ceramic substrate layer 1, leaving the bottom of at least another one of the electrode metal structures 2″ (e.g., the right electrode metal structure 2″ in FIG. 8B) not connected to the thin gold connection layer Aup.

Step S806 includes forming a covered thick gold Au22′ covering on the top surface and sidewalls of the electrode metal structure 2″ corresponding to the covered thick gold plating area A22 through electroplating, based on the second selective plating area A2 of the second pattern mask P2, thereby defining a covered thick gold electrode metal structure 2b″.

Additionally, at least another one of the electrode metal structures 2″ that is covered by the second pattern mask P2 or not connected to the thin gold connection layer Aup (e.g., the left and right electrode metal structures 2″ in FIG. 8B) is not plated with thick gold, thereby defining at least one non-thick-gold-plated electrode metal 2c″.

As shown in FIG. 8C, step S807 includes stripping and removing the second pattern mask P2 from the ceramic substrate layer 1, thereby exposing the covered thick gold electrode metal structure 2b″ and the non-thick-gold-plated electrode metals 2c″ to the external environment.

A third selective plating operation is performed, which includes steps S808 to S810.

Step S808 includes forming and covering a third pattern mask P3 on the covered thick gold electrode metal structure 2b″ and at least one of the non-thick-gold-plated electrode metals 2c″ (e.g., the left non-thick-gold-plated electrode metal 2c″ in FIG. 8C). The third pattern mask P3 fully covers the non-thick-gold-plated electrode metal 2c″ and partially covers the covered thick gold electrode metal structure 2b″, leaving at least a portion of the top surface of the covered thick gold Au22′ of the covered thick gold electrode metal structure 2b″ exposed through a third selective plating area A3 defined by the third pattern mask P3, thereby defining a bonding metal layer plating area on the covered thick gold Au22′ (i.e., A3).

Step S809 includes forming a bonding metal layer BL protruding on the thick gold layer Au2′ (covered thick gold Au22′) of the covered thick gold electrode metal structure 2b″ through physical vapor deposition or electroplating, based on the third selective plating area A3 of the third pattern mask P3. The material of the bonding metal layer BL is at least one of platinum and gold-tin (AuSn) alloy, but the present disclosure is not limited thereto.

As shown in FIG. 8D, step S810 includes stripping and removing the third pattern mask P3 from the ceramic substrate layer 1 and etching away the exposed thin gold connection layer Aup, thereby exposing the covered thick gold electrode metal structure 2b″ and the non-thick-gold-plated electrode metal 2c″ once again, so as to complete the preparation of the metallized ceramic substrate E8 of the eighth embodiment. The metallized ceramic substrate E8 of the present embodiment includes at least one covered thick gold electrode metal structure 2b″ and at least one non-thick-gold-plated electrode metal 2c″ which are independently disposed, in which the bonding metal layer BL is formed on the covered thick gold Au22′.

### Ninth Embodiment

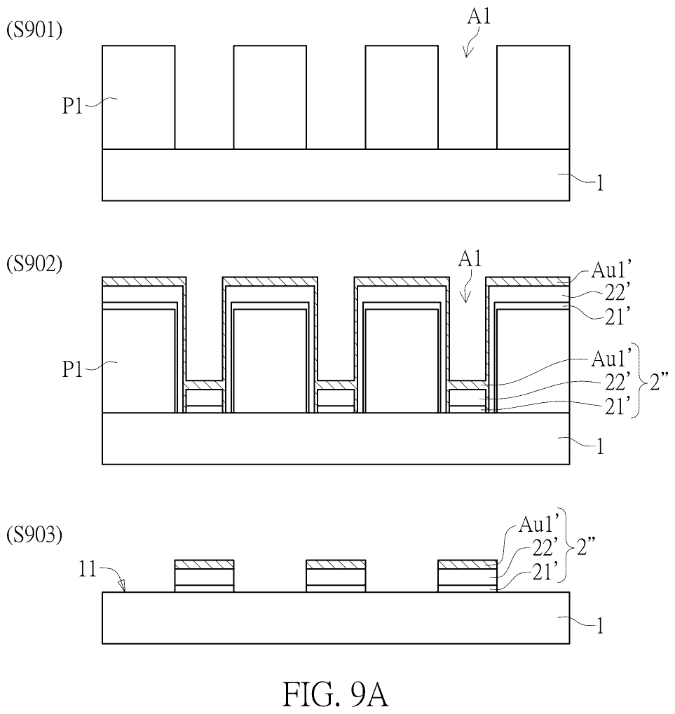

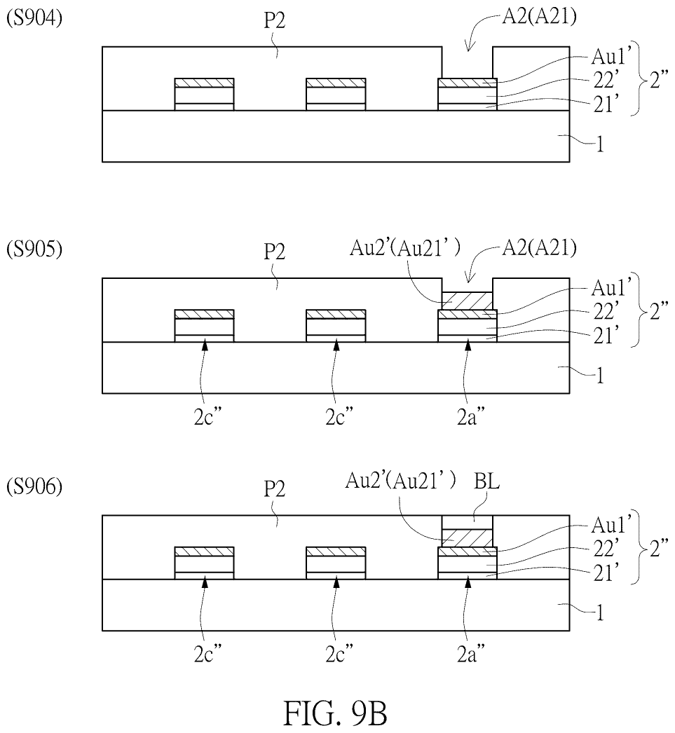

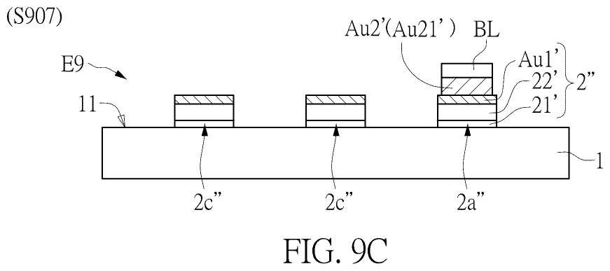

Referring to FIGS. 9A to 9C, the manufacturing method of the metallized ceramic substrate E9 of the ninth embodiment of the present disclosure includes the following steps of S901 to S907.

A first selective plating operation is performed, which includes steps S901 to S903.

As shown in FIG. 9A, step S901 includes providing a ceramic substrate layer 1 and forming a first pattern mask P1 on the ceramic substrate layer 1, in which the first pattern mask P1 defines a first selective plating area A1, and the first selective plating area A1 at least partially exposes a surface 11 of the ceramic substrate layer 1.

Step S902 includes sequentially forming a first metal layer 21′ (e.g., a titanium layer), a second metal layer 22′ (e.g., a platinum layer), and a thin gold layer Au1′ on the exposed surface 11 of the ceramic substrate layer 1 through evaporation, sputtering, or physical vapor deposition, based on the first selective plating area A1 of the first pattern mask P1, so as to form at least one electrode metal structure 2″ on an exposed surface 11 of the ceramic substrate layer 1 in the first selective plating area A1.

Similar to the seventh embodiment described above, in the present embodiment, the first metal layer 21′, the second metal layer 22′, and the thin gold layer Au1′ also extend to cover the inner sidewalls and top surface of the first pattern mask P1 located in the first selective plating area A1, but the present disclosure is not limited thereto.

Step S903 includes removing the first pattern mask P1 (and the first metal layer 21′, the second metal layer 22′, and the thin gold layer Au1′ covering thereon) from the ceramic substrate layer 1, so that the at least one electrode metal structure 2″ is independently disposed on the surface 11 of the ceramic substrate layer 1.

In the present embodiment, the quantity of the electrode metal structures 2″ is plural as shown in FIG. 9A, which shows three electrode metal structures 2″ (e.g., left, middle, and right electrode metal structures 2″), but the present disclosure is not limited thereto.

A second selective plating operation is performed, which includes steps S904 to S907.

Step S904 includes forming a second pattern mask P2 on the ceramic substrate layer 1, in which the second pattern mask P2 defines a second selective plating area A2, which includes a protruded thick gold plating area A21 corresponding to at least one of the plurality of electrode metal structures 2″ (e.g., the rightmost electrode metal structure 2″ in FIG. 9B), to partially cover and partially expose the top surface of the thin gold layer Au1′ of that electrode metal structure 2″. Further, the second pattern mask P2 fully covers at least another one of the plurality of electrode metal structures 2″ (e.g., the left and middle electrode metal structures 2″ in FIG. 9B).

Step S905 includes forming a protruded thick gold Au21′ on the top surface of the thin gold layer Au1′ of the electrode metal structure 2″ corresponding to the protruded thick gold plating area A21 through electro-less plating, based on the second selective plating area A2 of the second pattern mask P2, thereby defining a protruded thick gold electrode metal structure 2a″.

Additionally, at least another one of the electrode metal structures 2″ that is fully covered by the second pattern mask P2 is not plated with thick gold, thereby defining at least one non-thick-gold-plated electrode metal 2c″.

In the present embodiment, the height of the protruded thick gold Au21′ is lower than the top surface of the second pattern mask P2, allowing the second selective plating area A2 to reserve a bonding metal layer plating area.

Step S906 includes forming a bonding metal layer BL on the protruded thick gold Au21′ of the protruded thick gold electrode metal structure 2a″ through physical vapor deposition or electroplating, based on the bonding metal layer plating area reserved in the second selective plating area A2.

As shown in FIG. 9C, step S907 includes removing the second pattern mask P2 from the ceramic substrate layer 1, thereby exposing the protruded thick gold electrode metal structure 2a″ and the non-thick-gold-plated electrode metals 2c″, which are electrically insulated from each other, so as to complete the preparation of the metallized ceramic substrate E9 of the ninth embodiment.

### Tenth Embodiment

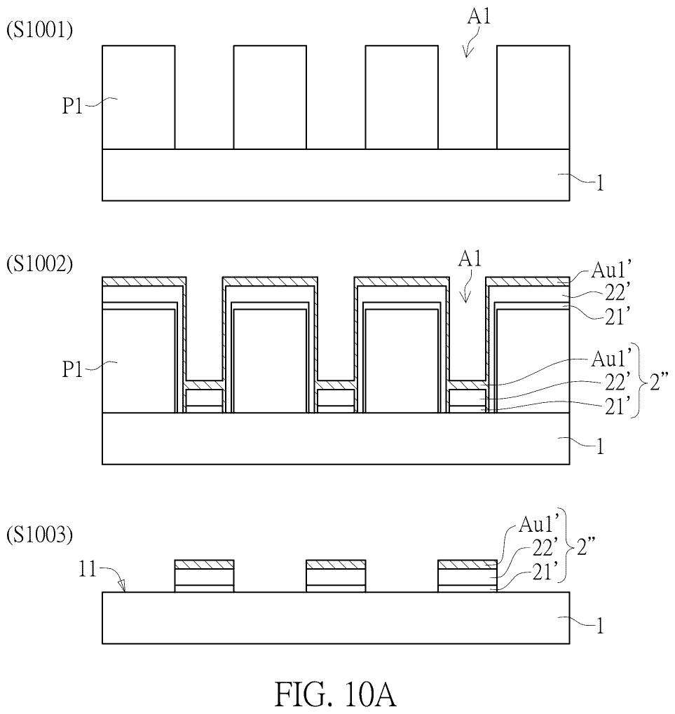

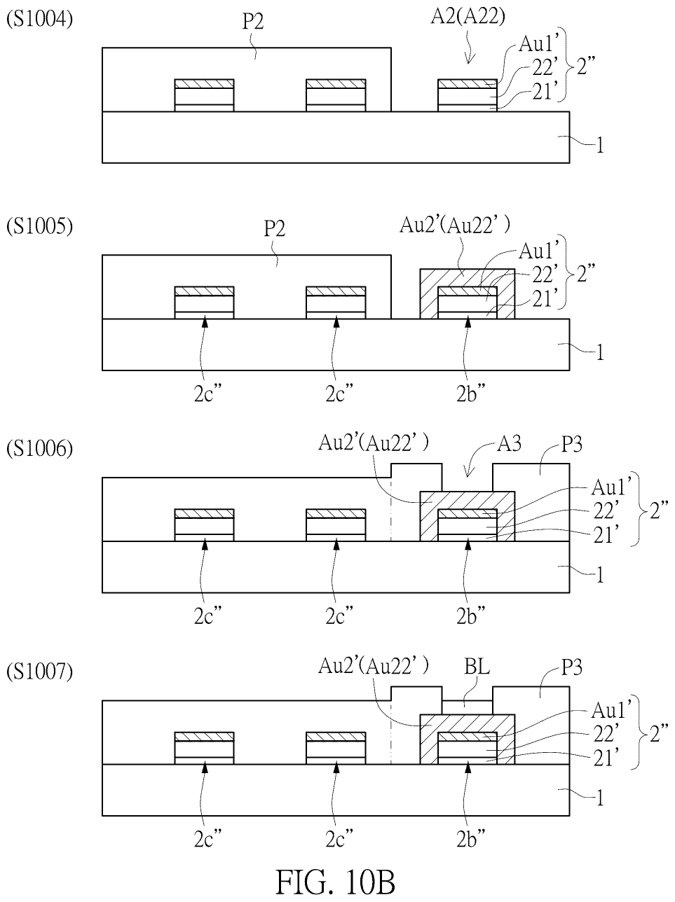

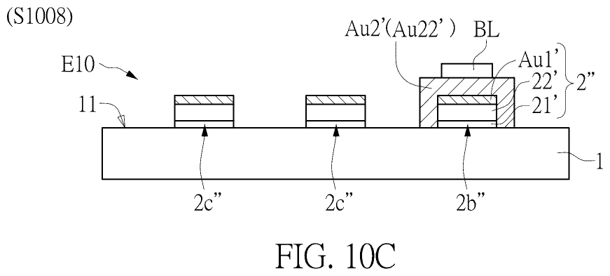

Referring to FIGS. 10A to 10C, the manufacturing method of the metallized ceramic substrate E10 of the tenth embodiment of the present disclosure includes the following steps of S1001 to S1008.

A first selective plating operation is performed, which includes steps S1001 to S1003.

As shown in FIG. 10A, step S1001 includes providing a ceramic substrate layer 1 and forming a first pattern mask P1 on the ceramic substrate layer 1, in which the first pattern mask P1 defines a first selective plating area A1, and the first selective plating area A1 at least partially exposes a surface 11 of the ceramic substrate layer 1.

Step S1002 includes sequentially forming a first metal layer 21′ (e.g., a titanium layer), a second metal layer 22′ (e.g., a platinum layer), and a thin gold layer Au1′ on an exposed surface 11 of the ceramic substrate layer 1 through evaporation, sputtering, or physical vapor deposition, based on the first selective plating area A1 of the first pattern mask P1, so as to form at least one electrode metal structure 2″ on the exposed surface 11 of the ceramic substrate layer 1 in the first selective plating area A1.

Step S1003 includes removing the first pattern mask P1 from the ceramic substrate layer 1 and leaving the at least one electrode metal structure 2″ on the surface 11 of the ceramic substrate layer 1.

In the present embodiment, the quantity of the electrode metal structures 2″ is plural as shown in FIG. 10A, which shows three electrode metal structures 2″ (e.g., left, middle, and right electrode metal structures 2″) that are independently disposed, but the present disclosure is not limited thereto.

As shown in FIG. 10B, step S1004 includes forming a second pattern mask P2 on the ceramic substrate layer 1, in which the second pattern mask P2 defines a second selective plating area A2, which includes a covered thick gold plating area A22. The covered thick gold plating area A22 corresponds to at least one of the electrode metal structures 2″ (e.g., the rightmost electrode metal structure 2″ in FIG. 10B) to fully expose the sidewalls and the surface of the thin gold layer Au1′ of the electrode metal structure 2″. The second pattern mask P2 also fully covers at least another one of the electrode metal structures 2″ (e.g., the left and middle electrode metal structures 2″ in FIG. 10B).

Step S1005 includes forming a covered thick gold Au22′ that covers the top surface and sidewalls of the electrode metal structure 2″ corresponding to the covered thick gold plating area A22 through electro-less plating, based on the second selective plating area A2 of the second pattern mask P2, thereby defining a covered thick gold electrode metal structure 2b″.

Additionally, at least another one of the electrode metal structures 2″ that is fully covered by the second pattern mask P2 is not plated with thick gold, thereby defining at least one non-thick-gold-plated electrode metal 2c″.

A third selective plating operation is performed, which includes steps S1006 to S1008.

Step S1006 includes forming and covering a third pattern mask P3 on the covered thick gold electrode metal structure 2b″, in which the third pattern mask P3 partially covers the covered thick gold electrode metal structure 2b″ and at least partially exposes the top surface of the covered thick gold Au22′ of the covered thick gold electrode metal structure 2b″ through a third selective plating area A3 defined by the third pattern mask P3, to define a bonding metal layer plating area on the top surface of the covered thick gold Au22′.

It is worth mentioning that in the present embodiment, the third pattern mask P3 is applied over the covered thick gold electrode metal structure 2b″ without removing the second pattern mask P2, and the top surface of the third pattern mask P3 is slightly higher than that of the second pattern mask P2, but the present disclosure is not limited thereto.

Step S1007 includes forming a bonding metal layer BL protruding on the thick gold layer Au2′ (covered thick gold Au22′) of the covered thick gold electrode metal structure 2b″ through physical vapor deposition, based on the third selective plating area A3 of the third pattern mask P3. The bonding metal layer BL can be composed of materials such as platinum or a gold-tin (AuSn) alloy.

As shown in FIG. 10C, step S1008 includes removing the third pattern mask P3 and the second pattern mask P2 from the ceramic substrate layer 1, thereby exposing the covered thick gold electrode metal structure 2b″ and the non-thick-gold-plated electrode metal 2c″ to complete the preparation of the metallized ceramic substrate E10 of the tenth embodiment. The metallized ceramic substrate E10 of the present embodiment includes at least one covered thick gold electrode metal structure 2b″ and at least one non-thick-gold-plated electrode metal 2c″ independently disposed on the ceramic substrate layer 1, in which the bonding metal layer BL is formed on the thick gold layer Au2′ (covered thick gold Au22′) of the covered thick gold electrode metal structure 2b″.

### Beneficial Effects of the Embodiments

In conclusion, the first pattern mask and the second pattern mask of the metallized ceramic substrate and a manufacturing method thereof according to the present disclosure can be used in combination to form thick gold structures in the first selective plating area and the second selective plating area, which are necessary for subsequent processes involving die bonding or wire bonding.

The metallized ceramic substrate of the embodiments of the present disclosure addresses several technical challenges, including eliminating the need for tie bar conductors, and effectively resolving the issue of burrs created during the singulation process.

The manufacturing process can be streamlined by replacing the solder ball mounting step with electroplating or electroless plating of thick gold layers. Additionally, costs can be reduced by selectively patterning the thick gold plating according to practical requirements. Furthermore, the reliability of the substrate is enhanced by minimizing copper exposure, improving corrosion resistance, and increasing oxidation resistance.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching. The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for manufacturing a metallized ceramic substrate, comprising:
providing a ceramic substrate layer;
performing a first selective plating operation that includes: forming at least one electrode metal structure protruding on a surface of the ceramic substrate layer based on a first selective plating area of a first pattern mask, wherein an outer layer of the at least one electrode metal structure away from the ceramic substrate layer is a thin gold layer, and the thin gold layer has a first thickness; and
performing a second selective plating operation that includes: forming a thick gold layer on the thin gold layer of the at least one electrode metal structure based on a second selective plating area of a second pattern mask, wherein the thick gold layer has a second thickness;
wherein the second thickness is greater than the first thickness.

2. The method for manufacturing the metallized ceramic substrate according to claim 1, wherein the first thickness of the thin gold layer is between 0.06 micrometers and 0.2 micrometers, and the second thickness of the thick gold layer is between 0.5 micrometers and 25 micrometers.

3. The method for manufacturing the metallized ceramic substrate according to claim 1, wherein the thick gold layer is a protruded thick gold on the at least one electrode metal structure, the protruded thick gold is partially disposed and covered on a top surface of the thin gold layer, and exposes another part of the top surface of the thin gold layer, and wherein a width of the thick gold layer is less than a width of the thin gold layer.

4. The method for manufacturing the metallized ceramic substrate according to claim 1, wherein the thick gold layer is a covered thick gold on the at least one electrode metal structure, the covered thick gold fully covers a top surface of the thin gold layer and extends to cover a sidewall of the electrode metal structure, so as to cover around the electrode metal structure.

5. The method for manufacturing the metallized ceramic substrate according to claim 1, further comprising:
performing a third selective plating operation that includes: forming a bonding metal layer on the thick gold layer based on a third selective plating area of a third pattern mask; wherein the bonding metal layer is made of at least one of platinum and gold-tin alloy.

6. The method for manufacturing the metallized ceramic substrate according to claim 1, wherein the at least one electrode metal structure includes a first metal layer, a second metal layer, a third metal layer, a fourth metal layer, and the thin gold layer sequentially stacked on the ceramic substrate layer, wherein the first metal layer is a sputtered titanium layer, the second metal layer is a sputtered copper layer, the third metal layer is an electroplated copper layer, the fourth metal layer is an electroplated nickel layer, and the thin gold layer is an electroplated thin gold layer, wherein the thin gold layer is in direct contact with the thick gold layer.

7. The method for manufacturing the metallized ceramic substrate according to claim 1, wherein a quantity of the at least one electrode metal structure is plural, and a plurality of electrode metal structures include a first electrode metal and a second electrode metal; wherein a metal connection layer is connected to a bottom of the first electrode metal and a bottom of the second electrode metal.

8. The method for manufacturing the metallized ceramic substrate according to claim 1, wherein the at least one electrode metal structure includes a first metal layer, a second metal layer, and a third metal layer sequentially stacked on the ceramic substrate layer to form a metal pillar; wherein the first metal layer is a sputtered titanium layer, the second metal layer is a sputtered copper layer, and the third metal layer is an electroplated copper layer; wherein the at least one electrode metal structure further includes a precious metal covering layer that covers outsides of the metal pillar, and the precious metal covering layer includes the thin gold layer.

9. The method for manufacturing the metallized ceramic substrate according to claim 8, wherein the precious metal covering layer is a multi-layer covering structure that includes a first covering layer, a second covering layer, and the thin gold layer; wherein the first covering layer covers an outer surface of the metal pillar, the second covering layer covers an outer surface of the first covering layer, and the thin gold layer covers an outer surface of the second covering layer; wherein the first covering layer is an electroless plated nickel layer, the second covering layer is an electroless plated palladium layer, and the thin gold layer is an electroless plated gold layer.

10. The method for manufacturing the metallized ceramic substrate according to claim 1, wherein the at least one electrode metal structure includes a first metal layer, a second metal layer, and the thin gold layer sequentially stacked on the ceramic substrate layer through vapor deposition, sputtering, or physical vapor deposition (PVD); wherein the first metal layer is a titanium layer, and the second metal layer is a platinum layer.

11. A metallized ceramic substrate, comprising:
a ceramic substrate layer;
at least one electrode metal structure protrudingly disposed on a surface of the ceramic substrate layer, wherein an outer layer of the at least one electrode metal structure away from the ceramic substrate layer is a thin gold layer, and the thin gold layer has a first thickness; and
a thick gold layer formed on the thin gold layer, wherein the thick gold layer has a second thickness;
wherein the second thickness is greater than the first thickness.

12. The metallized ceramic substrate according to claim 11, wherein the first thickness of the thin gold layer is between 0.06 micrometers and 0.2 micrometers, and the second thickness of the thick gold layer is between 0.5 micrometers and 25 micrometers.

13. The metallized ceramic substrate according to claim 11, wherein the thick gold layer is a protruded thick gold on the at least one electrode metal structure, the protruded thick gold is partially disposed and covered on a top surface of the thin gold layer, and exposes another part of the top surface of the thin gold layer.

14. The metallized ceramic substrate according to claim 11, wherein the thick gold layer is a covered thick gold on the at least one electrode metal structure, the covered thick gold fully covers a top surface of the thin gold layer and extends to cover a sidewall of the electrode metal structure, so as to cover around the electrode metal structure.

15. The metallized ceramic substrate according to claim 11, further comprising: a bonding metal layer formed on the thick gold layer; wherein a material of the bonding metal layer is at least one of platinum and gold-tin alloy.

16. The metallized ceramic substrate according to claim 11, wherein the at least one electrode metal structure includes a first metal layer, a second metal layer, a third metal layer, a fourth metal layer, and the thin gold layer sequentially stacked on the ceramic substrate layer, wherein the first metal layer is a sputtered titanium layer, the second metal layer is a sputtered copper layer, the third metal layer is an electroplated copper layer, the fourth metal layer is an electroplated nickel layer, and the thin gold layer is an electroplated thin gold layer, and wherein the thin gold layer is in direct contact with the thick gold layer.

17. The metallized ceramic substrate according to claim 11, wherein a quantity of the at least one electrode metal structure is plural, and a plurality of electrode metal structures include a first electrode metal and a second electrode metal; wherein a metal connection layer is connected to a bottom of the first electrode metal and a bottom of the second electrode metal.

18. The metallized ceramic substrate according to claim 11, wherein the at least one electrode metal structure includes a first metal layer, a second metal layer, and a third metal layer sequentially stacked on the ceramic substrate layer to form a metal pillar; wherein the first metal layer is a sputtered titanium layer, the second metal layer is a sputtered copper layer, and the third metal layer is an electroplated copper layer; wherein the at least one electrode metal structure further includes a precious metal covering layer that covers outsides of the metal pillar, and the precious metal covering layer includes the thin gold layer.

19. The metallized ceramic substrate according to claim 18, wherein the precious metal covering layer is a multi-layer covering structure that includes a first covering layer, a second covering layer, and the thin gold layer; wherein the first covering layer covers an outer surface of the metal pillar, the second covering layer covers an outer surface of the first covering layer, and the thin gold layer covers an outer surface of the second covering layer; wherein the first covering layer is an electroless plated nickel layer, the second covering layer is an electroless plated palladium layer, and the thin gold layer is an electroless plated gold layer.

20. The metallized ceramic substrate according to claim 11, wherein the at least one electrode metal structure includes a first metal layer, a second metal layer, and the thin gold layer sequentially stacked on the ceramic substrate layer through vapor deposition, sputtering, or physical vapor deposition (PVD); wherein the first metal layer is a titanium layer, and the second metal layer is a platinum layer.
